(19) United States
(12) Patent Application Publication
(10) Pub. No.: US 2004/0140483 A1
(43) Pub. Date: Jul. 22, 2004

(54) Semiconductor integrated circuit and fabrication method for same

(75) Inventor: Masashi Yonemaru, Chiba-shi (JP)

Correspondence Address: NIXON & VANDERHYE, PC, 1100 N GLEBE ROAD, 8TH FLOOR, ARLINGTON, VA, 22201-4714, US

(73) Assignee: Sharp Kabushiki Kaisha, Osaka (JP)

(21) Appl. No.: 10/720,764

(22) Filed: Nov. 25, 2003

(30) Foreign Application Priority Data
Nov. 25, 2002 (JP) 2002-341507

(51) Int. Cl. H01L 21/82; H01L 27/10

(52) U.S. Cl. 257/204; 438/128; 257/206; 438/129; 257/208

(57) ABSTRACT

A semiconductor integrated circuit is provided, which comprises a first cell comprising a plurality of transistors, a second cell comprising a PMOS transistor section and an NMOS transistor section, the PMOS transistor section comprising a first PMOS transistor and a second PMOS transistor connected to the first PMOS transistor in series, the NMOS transistor section comprising a first NMOS transistor and a second NMOS transistor connected to the first NMOS transistor in series. A predetermined scheme is used to connect between the first cell and the second cell, between the plurality of transistors in the first cell, and between the PMOS transistor section and the NMOS transistor section in the second cell.

### BACKGROUND OF THE INVENTION

1. Field of the Invention

The present invention relates to a semiconductor integrated circuit and a fabrication method thereof. More particularly, a semiconductor integrated circuit which is a large-scale logic circuit realized by combining various basic gates, such as AND gates, OR gates, XOR gates, and the like, and a fabrication method thereof.

2. Description of the Related Art

Conventionally, large-scale logic circuits, such as ASICs (application specific integrated circuit), microprocessors, digital signal processing circuits, and the like, have been designed and fabricated in a standard cell scheme, a gate array scheme, or the like. In these schemes, for example, basic gates, such as AND gates (logical multiplication gates), OR gates (logical addition gates), XOR gates (exclusive logical addition gates), and the like, are prepared in advance, these basic gates are combined to design a large-scale logic circuit, and a large-scale logic circuit is actually fabricated based on the design.

For example, in the gate array scheme, a plurality of arrays of basic cells comprising a plurality of transistors are arranged on a substrate, and the transistors in the basic cells are interconnected by wiring to form a basic logic circuit (basic gate). A wiring passage (wiring channel) for interconnecting basic gates is provided between each basic cell array. The total wiring between the basic gates is made short and simple by determining the arrangement of basic gates and the pattern of wiring between the basic gates using a computer. The arrangement of basic gates is determined by the pattern of wiring between the transistors in the basic cells.

In the standard cell scheme, basic gates and more complex logic circuits comprising a combination of basic gates are registered as standard cells in libraries of a computer in advance, and these standard cells are combined into a large-scale logic circuit. In this case, a plurality of arrays of required standard cells are arranged on a substrate. The total of wiring length between each standard cell is minimized by determining the arrangement of standard cells, a wiring pattern, and the width of a wiring channel (a region between a standard cell array and its adjacent standard cell array) using a computer.

In the standard cell scheme or the gate array scheme, a computer aided design (CAD) program is used to combine and arrange cells including the basic gates, the standard cells, and the like, on a semiconductor substrate and provide wiring between the cells to form a large-scale logic integrated circuit. Typically, several tens of types of cells are required.

In order to obtain a large-scale logic circuit with a smaller number of types of cells, standard cells including a pass transistor circuit and a buffer circuit are employed, for example. By connecting the terminals of the pass transistor circuits to form a plurality of types of logic gates, the number of types of cells can be reduced. This technique is described in, for example, Japanese Laid-Open Publication No. 7-130856. The conventional technique will be described below.

FIGS. 24A, 24B, and 24C are diagrams showing an exemplary conventional standard cell as disclosed in Japanese Laid-Open Publication No. 7-130856 where an exemplary cell library for one cell PC1 is illustrated. FIG. 24A is a perspective view of the outer appearance of the cell PC1. FIG. 24B is a circuit diagram of the cell PC1. FIG. 24C is a layout diagram of the cell PC1.

As shown in FIGS. 24A through 24C, the cell PC1 has an outer shape of a rectangular prism having an upper surface of 35 μm in width and 10 μm in length. The cell PC1 has I/O terminals 101 to 108 at the upper portion thereof.

As shown in FIG. 24C, in the cell PC1, first operating potential supply line (source voltage line Vcc) and a second operating potential supply line (ground line GND) are arranged in parallel to each other. NMOS transistors M101 to M104, an output inverter I1, and a pull-up PMOS transistor Mp′ are provided between the source voltage line Vcc and the ground line GND. The output inverter I1 comprises a PMOS transistor Mp and an NMOS transistor Mn.

In the cell PC1, the gate electrode of the NMOS transistor M101 is connected to the input terminal 101. The gate electrode of the NMOS transistor M102 is connected to the input terminal 102. The gate electrode of the NMOS transistor M103 is connected to the input terminal 103. The gate electrode of the NMOS transistor M104 is connected to the input terminal 104.

The source of the NMOS transistor M101 is connected to the input terminal 107. The drain of the NMOS transistor M101 is connected to a node 102

The source of the NMOS transistor M102 is connected to the node N101. The drain of the NMOS transistor M102 is connected to the node N102.

The source of the NMOS transistor M103 is connected to the input terminal 106. The drain of the NMOS transistor M103 is connected to the node N101.

The source of the NMOS transistor M104 is connected to the input terminal 105. The drain of the NMOS transistor M104 is connected to the node N101.

In the output inverter I1, the source of the PMOS transistor Mp is connected to the source voltage line Vcc and the source of the NMOS transistor Mn is connected to the ground line GND. Therefore, a source voltage is supplied to the cell PC1. The gate electrodes of the PMOS transistor Mp and the NMOS transistor Mn, which are inputs of the output inverter I1, are connected to the node N102. The drains of the PMOS transistor Mp and the NMOS transistor Mn, which are outputs of the output inverter I1, are connected to the output terminal 108. The pull-up PMOS transistor Mp′ is provided between the source voltage line Vcc and the node N102. The gate electrode of the pull-up PMOS transistor Mp′ is connected to the output terminal 108.

In the cell PC1, the internal circuit of the cell PC1 is divided into a binary tree: a pair of the NMOS transistors M101 and M102 and a pair of the NMOS transistors M103 and M104. A mask pattern layout corresponding to this circuit connection is prepared in advance. The cell PC1 is provided with the four gate input terminals 101 to 104 and the output terminal 108. The input terminals 105 to 107 connected to the drains of the NMOS transistors M101, M1013 and M104 are open. By changing a signal externally input to the input terminals 105 to 107, different logic outputs can be obtained.

FIG. 25 is a perspective view of the outer appearance of the cell PC1 for explaining that various logic functions can be obtained by changing signals applied to the input terminals 105 to 107.

In FIG. 25, signals A, AN, B, and BN are applied to the gate input terminals 101 to 104, respectively, where the suffix N of the signal represents a complementary signal. The input terminals 105 and 107 are connected to GND. A signal C is applied to the input terminal 106 independently of the input terminals 101 to 105 and 107. In this case, the input terminal 101=A, the input terminal 102=AN, the input terminal 103=B, the input terminal 104=BN, the input terminal 105=0, the input terminal 106=C, and the input terminal 107=0. The output terminal 108 outputs:

(108)=(((105)×(104)+(106)×(103))×(102)+(107)×(101))×N (108)=((AN)×B×C)×N.

Thus, a 3-input NAND function is obtained (A is a negative logic). Similarly, other logic operating functions can be obtained.

As described above, the conventional technique as disclosed in Japanese Laid-Open Publication No. 7-130856 can provide a plurality of types of logic operations using pass transistor circuits and buffer circuits (inverter circuits), thereby making it possible to provide a number of logic circuits using a small number of cells.

However, measures for low voltage operation and low standby leakage current required for low power consumption and miniaturization are not taken into consideration in the conventional technique as disclosed in Japanese Laid-Open Publication No. 7-130856.

Conventionally, standby leakage current in semiconductor integrated circuits is reduced by providing a flip-flop circuit with a leakage reduction circuit in a pipeline operation random logic circuit and turning off a voltage source for the random logic circuit at the time of standby (e.g., see Japanese Laid-Open Publication No. 2000-332598). Hereinafter, this conventional technique will be described.

FIG. 26 is a block diagram showing the configuration of a conventional random logic circuit 200 as disclosed in Japanese Laid-Open Publication No. 2000-332598.

In FIG. 26, the random logic circuit 200 has buffer circuits 201 to 206, flip-flop circuits (F/F) 207 to 212, 216 to 221, 225 to 230, and 234 to 239, and logic circuits 213 to 215, 222 to 224, and 231 to 233.

Externally input signals are processed by the buffer circuit 201 to 206, the flip-flop circuits (F/F) 207 to 212, the logic circuit 213 to 215, the flip-flop circuit (F/F) 216 to 221, the logic circuit 222 to 224, the flip-flop circuits (F/F) 225 to 230, the logic circuits 231 to 233, and the flip-flop circuits (F/F) 234 to 239 in this order, respectively. A source voltage VCCO is connected to the buffer circuits 201 to 206, the flip-flop circuits (F/F) 207 to 212, 216 to 221, 225 to 230, and 234 to 239, and the logic circuit 213 to 215, 222 to 224, and 231 to 233. In the normal mode the source voltage VCC0 is supplied, while in the standby mode the source voltage VCC0 is not supplied (OFF state). Source voltages VCC1 are connected to the flip-flop circuits (F/F) 207 to 212, 216 to 221, 225 to 230, and 234 to 239. Both in the normal and standby modes, the source voltage VCC1 is supplied.

FIG. 27 is a circuit diagram showing the circuit configuration of a conventional flip-flop circuit (F/F) as disclosed in Japanese Laid-Open Publication No. 2000-332598.

In FIG. 27, the flip-flop circuit comprises a master stage comprising an inverter circuit 261 and a latch circuit 262, and a slave stage comprising a latch circuit 263 and an inverter circuit 264. The master stage latch circuit 262 is separated from the slave stage latch circuit 263 by a transfer gate 250.

The master stage inverter circuit 261 comprises PMOS transistors 240 and 241 connected in series and NMOS transistors 242 and 243 connected in series. The subsequent master stage latch circuit 262 comprises: an inverter circuit 262a comprising a PMOS transistor 244 and an NMOS transistor 245; and an inverter circuit 262b comprising PMOS transistors 246 and 247 connected in series and NMOS transistors 248 and 249 connected in series. The slave stage latch circuit 263 comprises: an inverter circuit 263a comprising a PMOS transistor 251 and an NMOS transistor 252; and an inverter circuit 263b comprising PMOS transistors 253 and 254 connected in series and NMOS transistors 255 and 256 connected in series. The subsequent slave stage inverter circuit 264 comprises a PMOS transistor 257 and an NMOS transistor 258. The transfer gate 250 is interposed between the inverter circuits 262 and 263, comprising a PMOS transistor 250a and an NMOS transistor 250b connected in parallel.

The transfer gate 250 is controlled with control signals TG2 and TG2B. The master stage inverter circuit 261 and the master stage latch circuit 262 are controlled with control signals TG1 and TG1B. The slave stage latch circuit 263 is controlled with the control signals TG2 and TG2B. Here, the suffix B indicates an inverted signal. The level of each signal is a VCC level or a Vss level during the normal operation.

Level conversion circuits 259 and 260 convert the signal levels (potentials) of the control signals TG2 and TG2B; output the control signals TG2 and TG2B at the VCC level or the Vss level during the normal operation; and output the control signals TG2 and TG2B at potentials higher than the VCC level or lower than the Vss level in the standby mode.

During the normal operation of the flip-flop circuit, a source voltage is supplied to VCCO and VCC1 and a flip-flop operation is performed. In the standby mode, the source voltage VCCO supplied to the master stage latch circuit 262 is in the OFF state, while the source voltage VCC1 is applied to the slave stage latch circuit 263 so that data is retained. In this case, the transfer gate 250 between the master stage latch circuit 262 and the slave stage latch circuit 263 is in the OFF state, while a negative voltage is applied to each of the gates of the PMOS transistor 250a and the NMOS transistor 250b constituting the transfer gate 250 via the level conversion circuits 259 and 260, respectively, thereby reducing a sub-threshold leakage current. The transistors in the data retaining section (latch circuit 263) to which the source voltage VCC1 is supplied have a threshold higher than that of transistors in other sections, thereby reducing a leakage current.

Thus, in the conventional technique as disclosed in Japanese Laid-Open Publication No. 2000-332598, a flip-flop circuit for retaining data can be designed so that a leakage current in the standby mode can be reduced.

According to the conventional technique as disclosed in Japanese Laid-Open Publication No. 7-130856, a pass transistor circuit and a buffer (inverter) circuit can be used to perform a plurality of types of logic operations, whereby a number of logic circuits can be obtained with a small number of cells. In this conventional technique, a cell is constructed with a plurality of NMOS transistors constituting a pass transistor circuit, and a PMOS transistor and an NMOS transistor constituting an inverter circuit, whereby a plurality of types of logic operation can be provided. However, the size of the cell is large. Also, measures for low voltage operation and low standby leakage current required for low power consumption and miniaturization are not taken into consideration.

According to the conventional technique as disclosed in Japanese Laid-Open Publication No. 2000-332598, a flip-flop circuit for retaining data is designed so that leakage current can be reduced in the standby state. In this conventional technique, a source voltage section is provided with a source voltage switch for performing the ON/OFF control of a source voltage to be supplied to a random logic circuit or the like. In a typical MOS circuit, the above-described ON/OFF control is achieved by a MOS transistor switch. However, since the MOS transistor switch has a certain level of ON resistance, the source voltage potential of a random logic circuit fluctuates due to an IR drop (voltage drop) caused by a current consumed during operations, leading to deterioration of operating characteristics. Particularly in low voltage operations, such an influence is significant.

### SUMMARY OF THE INVENTION

According to an aspect of the present invention, a semiconductor integrated circuit comprises: a first cell comprising a plurality of transistors; a second cell comprising a PMOS transistor section and an NMOS transistor section, the PMOS transistor section comprising a first PMOS transistor and a second PMOS transistor connected to the first PMOS transistor in series, the NMOS transistor section comprising a first NMOS transistor and a second NMOS transistor connected to the first NMOS transistor in series. A predetermined scheme is used to connect between the first cell and the second cell, between the plurality of transistors in the first cell, and between the PMOS transistor section and the NMOS transistor section in the second cell.

In one embodiment of this invention, the plurality of transistors in the first cell function as at least a part of a pass transistor logic network circuit.

In one embodiment of this invention, the predetermined scheme is a standard cell scheme or a gate array scheme.

In one embodiment of this invention, the first cell functions as a logic operation circuit for outputting data; and the second cell functions as at least one of a driver circuit for driving the logic operation circuit or a data retaining circuit for retaining data output by the logic operation circuit.

In one embodiment of this invention, the plurality of transistors in the first cell include a PMOS transistor or an NMOS transistor.

In one embodiment of this invention, the plurality of transistors in the first cell include a PMOS transistor and an NMOS transistor.

In one embodiment of this invention, the plurality of transistors in the first cell include a transistor having a threshold higher than a predetermined value.

In one embodiment of this invention, the first PMOS transistor, the second PMOS transistor, the first NMOS transistor, and the second NMOS transistor each comprise a gate, a source, and a drain; a first source voltage is applied to the source of the first PMOS transistor; a second source voltage is applied to the source of the first NMOS transistor; one of the gate of the first PMOS transistor and the gate of the second PMOS transistor is connected to an input terminal, an input signal being input to the input terminal, and the other is connected to a first gate control signal input terminal, a first gate control signal being input to the first gate control signal input terminal; one of the gate of the first NMOS transistor and the gate of the second NMOS transistor is connected to the input terminal, and the other is connected to a second gate control signal input terminal, a second gate control signal being input to the second gate control signal input terminal; and the drain of the second PMOS transistor and the drain of the second NMOS transistor are connected to an output terminal.

In one embodiment of this invention, the gate of the first PMOS transistor is connected to the input terminal; the gate of the second PMOS transistor is connected to the first gate control signal input terminal; the gate of the first NMOS transistor is connected to the input terminal; and the gate of the second NMOS transistor is connected to the second gate control signal input terminal.

In one embodiment of this invention, the gate of the first PMOS transistor is connected to the first gate control signal input terminal; the gate of the second PMOS transistor is connected to the input terminal; the gate of the first NMOS transistor is connected to the second gate control signal input terminal; and the gate of the second NMOS transistor is connected to the input terminal.

In one embodiment of this invention, a potential of one of the first gate control signal and the second gate control signal, whichever is higher than that of the other, is higher than a potential of the first source voltage; and a potential of one of the first gate control signal and the second gate control signal, whichever is lower than that of the other, is lower than a potential of the second source voltage.

In one embodiment of this invention, a threshold voltage of one of the first PMOS transistor and the second PMOS transistor is higher than a threshold voltage of the other; and a threshold voltage of one of the first NMOS transistor and the second NMOS transistor is higher than a threshold voltage of the other.

In one embodiment of this invention, at least one transistor of the first PMOS transistor, the second PMOS transistor, the first NMOS transistor, and the second NMOS transistor is provided with a body potential terminal; and a body potential of the at least one transistor is controlled via the body potential terminal.

In one embodiment of this invention, at least one transistor of the first PMOS transistor, the second PMOS transistor, the first NMOS transistor, and the second NMOS transistor is provided with a body electrode; and the body electrode is connected to the gate of the at least one transistor.

In one embodiment of this invention, the semiconductor integrated circuit further comprises: an inverter circuit comprising the second cell. A clock signal is input to the first gate control signal input terminal or the second gate control signal input terminal.

In one embodiment of this invention, the semiconductor integrated circuit further comprises: an inverter circuit comprising the second cell. A standby state control signal is input as the first gate control signal to the first gate control signal input terminal or as the second gate control signal to the second gate control signal input terminal, so that an operation of the inverter circuit is stopped in a standby state.

In one embodiment of this invention, the semiconductor integrated circuit further comprises: a data retaining circuit comprising a combination of a plurality of circuits comprising the second cell.

In one embodiment of this invention, the semiconductor integrated circuit further comprises: a circuit comprising the second cell. The circuit comprises a first block and a second block, and the circuit is controlled so that the first block is operated while the second block is in a standby state.

In one embodiment of this invention, the semiconductor integrated circuit further comprises: a driver circuit comprising the second cell. The driver circuit is driven with the first gate control signal or the second gate control signal; and the gate of the first PMOS transistor, the gate of the second PMOS transistor, the gate of the first NMOS transistor, and the gate of the second NMOS transistor are connected together.

In one embodiment of this invention, the plurality of transistors in the first cell, and the first PMOS transistor, the second PMOS transistor, the first NMOS transistor, and the second NMOS transistor in the second cell have a SOI (Silicon on Insulator) structure.

According to another aspect of the present invention, a method for fabricating a semiconductor integrated circuit comprises the steps of: automatically synthesizing the semiconductor integrated circuit by determining a wiring pattern between a first cell comprising a plurality of transistors and a second cell comprising a PMOS transistor section and an NMOS transistor section, a wiring pattern between the plurality of transistors in the first cell, and a wiring pattern between the PMOS transistor section and the NMOS transistor section in the second cell in accordance with a predetermined scheme using a computer, wherein the PMOS transistor section comprises a first PMOS transistor and a second PMOS transistor connected to the first PMOS transistor in series, and the NMOS transistor section comprises a first NMOS transistor and a second NMOS transistor connected to the first NMOS transistor in series; and fabricating the automatically synthesized semiconductor integrated circuit.

In one embodiment of this invention, the predetermined scheme includes a standard cell scheme; the first cell and the second cell are registered as standard cells in the computer; the step of automatically synthesizing includes using the computer to automatically synthesize the semiconductor integrated circuit by determining the wiring pattern and wiring channel width between the first cell and the second cell, the wiring pattern and wiring channel width between the plurality of transistors in the first cell, and the wiring pattern and wiring channel width between the PMOS transistor section and the NMOS transistor section in the second cell.

In one embodiment of this invention, the predetermined scheme includes a gate array scheme; and

the automatically synthesizing step includes automatically synthesizing the semiconductor integrated circuit comprising the first cell and the second cell by using a substrate having a plurality of basic cell arrays comprising a basic cell comprising the first cell and the second cell using the computer.

Hereinafter, functions of the present invention will be described.

According to the present invention, two types of cell structures, i.e., a first cell comprising a plurality of transistors constituting a pass transistor logic network and a second cell comprising two PMOS transistors connected in series and two NMOS transistors connected in series, are prepared in a library of a computer. By using the standard cell scheme, an arbitrary logic circuit can be achieved.

Two types of cell structure, i.e., a first cell comprising a plurality of transistors constituting a pass transistor logic network and a second cell comprising two PMOS transistors connected in series and two NMOS transistors connected in series, are fabricated on a substrate in advance, the transistors in each cell are connected via the lower wiring layer, and cell connection is performed via an upper wiring layer. By using the gate array scheme, an arbitrary logic circuit can be achieved.

In either scheme, the cell structure can be simple and the cell size can be small compared to the conventional technique as disclosed in Japanese Laid-Open Publication No. 7-130856.

For example, a first cell can be used to construct a logic operation circuit, and a second cell is used to construct a driver circuit (e.g., an inverter buffer circuit) for driving the logic operation circuit, a data retaining circuit (e.g., a latch circuit, a flip-flop circuit, etc.) for retaining data output by the logic operation circuit, or the like.

The second cell comprises transistors connected in series, so that a source-drain voltage is divided. Therefore, a leakage current of even a low threshold transistor can be reduced as compared to a single transistor. With a logic circuit using a second cell, a leakage current in the standby state can be reduced without the ON/OFF control of the source voltage. In this case, the conventional technique as disclosed in Japanese Laid-Open Publication No. 2000-332598 is not required, in which the source voltage supplied to a random logic circuit and the like in an operation is ON/OFF controlled by as source voltage switch having a large IR drop value. Therefore, a deterioration in operating characteristics is not generated.

A first cell constituting a pass transistor logic network typically comprises NMOS transistors. However, a first cell may comprise PMOS transistors and NMOS transistors. In this case, it is possible to obtain a CMOS type pass transistor logic network in which PMOS transistors and NMOS transistors are complementarily used. By constructing a first cell using a transistor having a higher threshold than a predetermined value (normal threshold), a leakage current can be reduced as compared to when a first cell is constructed using a transistor having a lower threshold lower than the higher threshold.

In the second cell, the source (the input of the series circuit) of the PMOS transistors connected in series is connected to a first source voltage Vdd, while the source of the NMOS transistors connected in series (the input of the series circuit) is connected to a second source voltage Vss (GND); the gate of the PMOS transistor closer to the source of the series circuit (the input of the series circuit) is connected to the gate of the NMOS transistor closer to the source of the series circuit (the input of the series circuit) and the gates are used as an input terminal; the gate of the PMOS transistor closer to the drain of the series circuit (the output of the series circuit) and the gate of the NMOS transistor closer to the drain of the series circuit (the output of the series circuit) are used as gate control signal input terminals; and the drain of the PMOS transistor (the input of the series circuit) and the drain of the NMOS transistor (the input of the series circuit) are connected together as an output terminal. As a result, an inverter circuit constituting a buffer circuit, a flip-flop circuit, and the like are fabricated. Thereby, the circuit can be in the “OFF” state in a standby state, thereby making it possible to prevent waste standby current flow. In addition, by controlling the transistor closer to the drain of the series circuit (the output of the series circuit), current consumption due to transition feedback of an input signal can be suppressed, so that low power consumption can be achieved.

In the second cell, the source of the PMOS transistors (the input of the series circuit) connected in series is connected to a first source voltage Vdd, while the source of the NMOS transistors connected in series (the input of the series circuit) is connected to a second source voltage Vss (GND); the gate of the PMOS transistor closer to the drain (the output of the series circuit) is connected to the gate of the NMOS transistor closer to the drain and the gates are used as an input terminal; the gate of the PMOS transistor closer to the source (the input of the series circuit) and the gate of the NMOS transistor closer to the source (the input of the series circuit) are used as gate control signal input terminals; and the drain of the PMOS transistor (the output of the series circuit) and the drain of the NMOS transistor (the output of the series circuit) are connected together as an output terminal. As a result, an inverter circuit constituting a buffer circuit, a flip-flop circuit, and the like are fabricated. Thereby, the circuit can be in the “OFF” state in a standby state, thereby making it possible to prevent waste standby current flow. By controlling the transistor closer to the source (the input of the series circuit), a higher-speed operation can be obtained with respect to a change in an input signal.

By designing the higher potential of a gate control signal input to the gate control signal input terminal to be higher than the first source voltage Vdd to which the source of the PMOS transistor is connected, a leakage current is reduced when the PMOS transistor is in the “OFF” state. Therefore, power consumption in the standby state can be reduced. By designing the lower potential of a gate control signal input to the gate control signal input terminal to be lower than the second source voltage Vss (GND) to which the source of the NMOS transistor is connected, a leakage current can be reduced when the NMOS transistor is in the “OFF” state. Therefore, power consumption in the standby state can be reduced.

In the second cell, one of the transistors may be a high threshold transistor. In this case, a leakage current can be further reduced as compared to when a low threshold transistor is employed. Therefore, power consumption in the standby state can be reduced. One of the transistors is provided with a body potential terminal so that a body potential can be controlled, thereby making it possible to control a threshold voltage. During the normal operation the body potential is controlled so that a threshold voltage is low and a higher-speed operation is performed. In the standby state the body potential is controlled so that a threshold voltage is high and a leakage current is reduced. Therefore, power consumption in the standby state can be reduced.

The gate electrode and the body electrode of one of the transistors may be connected together. In this case, the body potential is automatically controlled so that when the transistor is in the “ON” state, the threshold voltage is low, and when the transistor is in the “OFF” state, the threshold voltage is high. Thereby, when the transistor is in the “ON” state, the threshold voltage is low and a driving ability is high, whereby a high-speed operation is possible. In addition, when the transistor is in the “OFF” state, the threshold voltage is high, thereby making it possible to reduce the leakage current.

In an inverter circuit using the second cell, a clock signal may be input to the gate control signal input terminal as a gate control signal. In this case, a clock gate circuit can be constructed. In addition, by inputting a standby state controlling signal to the gate control signal input terminal as a gate control signal, a circuit having a function of stopping an operation in the standby state can be constructed. A data retaining circuit, a driver circuit, and the like, which is constructed using the second cell, can be controlled so that only an active circuit block is in the operating state while an inactive circuit block is in the standby state (stop state). Thereby, only a circuit block required for an operation (calculation) is achieved, while other blocks are not achieved. Therefore, a standby current involved in a leakage current in this situation can be reduced, whereby power is not wasted. Thus, a low power consumption semiconductor integrated circuit can be achieved.

A driver circuit for driving a standby state control signal can be achieved by connecting the gates of PMOS transistors connected in series and the gates of NMOS transistors connected in series together in a second cell to construct an inverter circuit. The source-drain voltage of each transistor connected in series is lower than a source voltage since the source voltage is divided, thereby improving high voltage operations. Therefore, it is possible to easily construct a circuit to which a high voltage can be applied.

Transistors in the first cell and the second cell may have a SOI structure. In this case, a junction capacitance is small, thereby making it possible to achieve low power consumption. With the SOI structure, a steep sub-threshold characteristic is obtained. Therefore, even if a source-drain voltage is small, a large current is obtained compared to bulk MOS devices. The SOI structure transistor is suitable for bus network logic circuits. When a pass network transistor logic gate is made of a CMOS circuit, increases in area and parasitic capacitance can be reduced.

Thus, the invention described herein makes possible the advantages of providing a semiconductor integrated circuit and a fabrication method thereof, in which a plurality of types of logic functions are obtained using a small number of types of cells having a small cell size and a leakage current in the standby state is reduced, an influence of IR drop due to a source voltage switch is removed during an operation, so that operating characteristics can be improved.

These and other advantages of the present invention will become apparent to those skilled in the art upon reading and understanding the following detailed description with reference to the accompanying figures.

### BRIEF DESCRIPTION OF THE DRAWINGS

FIG. 1A is a layout diagram showing an exemplary cell pattern of a first cell constituting a pass transistor logic network according to Embodiment 1 of the present invention.

FIG. 1B is a layout diagram showing an exemplary cell pattern of a second cell comprising PMOS transistors connected in series and NMOS transistors connected in series according to Embodiment 1 of the present invention.

FIG. 2A is a circuit diagram showing the first cell of Embodiment 1 of the present invention.

FIG. 2B is a circuit diagram of the second cell of Embodiment 1 of the present invention.

FIG. 3 is a block diagram showing a configuration of a computer system for use in designing a semiconductor integrated circuit according to the present invention.

FIG. 4 is a circuit diagram showing an exemplary configuration of the semiconductor integrated circuit of Embodiment 1 of the present invention.

FIG. 5A is a layout diagram showing a cell pattern and wiring pattern of an inverter buffer circuit according to Embodiment 1 of the present invention.

FIG. 5B is a circuit diagram showing a circuit configuration of the inverter buffer circuit of FIG. 5A.

FIG. 6 is a layout diagram showing a cell pattern and wiring pattern of a pass transistor logic network section according to Embodiment 1 of the present invention.

FIG. 7A is a layout diagram showing a cell pattern and wiring pattern of a flip-flop circuit according to Embodiment 1 of the present invention.

FIG. 7B is a circuit diagram showing a circuit structure of the flip-flop circuit of FIG. 7A.

FIG. 7C is a timing chart showing an operating timing of the flip-flop circuit of FIG. 7A.

FIG. 8A is a layout diagram showing a cell pattern of a first cell constituting a pass transistor logic network according to Embodiment 2 of the present invention.

FIG. 8B is a circuit diagram showing a circuit configuration of the first cell of FIG. 8A.

FIG. 9A is a layout diagram showing a cell pattern and wiring pattern of a selector logic circuit according to Embodiment 2 of the present invention.

FIG. 9B is a circuit diagram showing a circuit configuration of the selector logic circuit of FIG. 9A.

FIG. 9C is a table showing a relationship between input signals SEL and SELB and an output signal Y.

FIG. 10A is a layout diagram showing a cell pattern and wiring pattern of an inverter circuit according to Embodiment 3 of the present invention.

FIG. 10B is a circuit diagram of the inverter circuit of FIG. 10A.

FIG. 11A is a circuit diagram showing a single transistor.

FIG. 11B is a circuit diagram showing a series connection transistor.

FIG. 11C is a graph showing characteristics of the single transistor of FIG. 11A.

FIG. 11D is a graph showing characteristics of the series connection transistor of FIG. 11B.

FIG. 12 is a graph showing characteristics of a transistor where the high potential of a gate control signal is higher than Vdd while the low potential thereof is lower than Vss.

FIG. 13A is a layout diagram showing a cell pattern and wiring pattern of an inverter circuit according to Embodiment 4 of the present invention.

FIG. 13B is a circuit diagram of the inverter circuit of FIG. 13A.

FIG. 14A is a layout diagram showing a cell pattern and wiring pattern of an inverter circuit according to Embodiment 5 of the present invention.

FIG. 14B is a circuit diagram showing a circuit configuration of the inverter circuit of FIG. 14A.

FIG. 15A is a layout diagram showing a cell pattern and wiring pattern of an inverter circuit according to Embodiment 6 of the present invention.

FIG. 15B is a circuit diagram showing a circuit configuration of the inverter circuit of FIG. 15A.

FIG. 16 is a layout diagram showing a cell pattern and wiring pattern of a data latch circuit according to Embodiment 7 of the present invention.

FIG. 17 is a circuit diagram showing a circuit configuration of the data latch circuit of FIG. 16.

FIG. 18 is a layout diagram showing a cell pattern and wiring pattern of a data latch circuit according to Embodiment 8 of the present invention.

FIG. 19 is a circuit diagram showing a circuit configuration of the data latch circuit of FIG. 18.

FIG. 20 is a block diagram showing a structure of a semiconductor integrated circuit fabricated according to Embodiment 9 of the present invention.

FIG. 21A is a layout diagram showing a cell pattern and wiring pattern of an inverter circuit according to Embodiment 10 of the present invention.

FIG. 21B is a circuit diagram showing a circuit configuration of the inverter circuit of FIG. 21A.

FIG. 22 is a cross-sectional view showing a structure of an SOI-structure transistor according to Embodiment 11 of the present invention.

FIG. 23 is a layout diagram showing a cell array pattern according to Embodiment 12 of the present invention.

FIG. 24A is a perspective view of the outer appearance of a conventional cell.

FIG. 24B is a circuit diagram of the cell of FIG. 24A.

FIG. 24C is a layout diagram of the cell of FIG. 24A.

FIG. 25 is a perspective view of the cell of FIG. 24A where an exemplary signal is applied to the cell.

FIG. 26 is a block diagram showing a configuration of a conventional random logic circuit.

FIG. 27 is a circuit diagram of a conventional flip-flop circuit.

### DESCRIPTION OF THE PREFERRED EMBODIMENTS

Hereinafter, the present invention will be described by way of illustrative embodiments 1 to 12 with reference to the accompanying drawings.

(Embodiment 1)

In Embodiment 1, an information processing apparatus within a computer determines the arrangement of standard cells, the wiring pattern in and between cells, and the width of a wiring channel, based on a program for the control of logic circuit synthesis in the standard cell scheme, using a library of the computer in which a first cell comprising a plurality of transistors constituting a pass transistor logic network and a second cell comprising two PMOS transistors connected in series and two NMOS transistors connected in series are registered as standard cells. As a result, a desired logic circuit is automatically synthesized and fabricated. The obtained semiconductor integrated circuit will be described below.

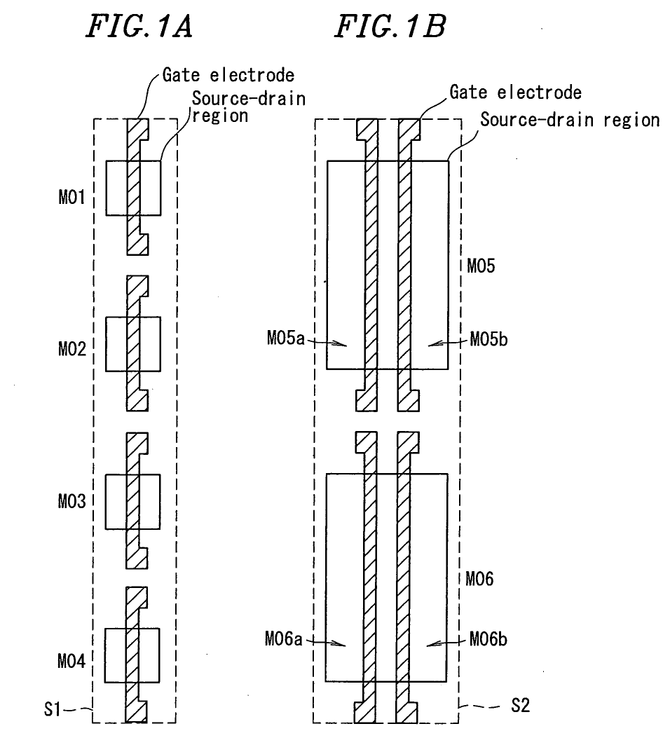

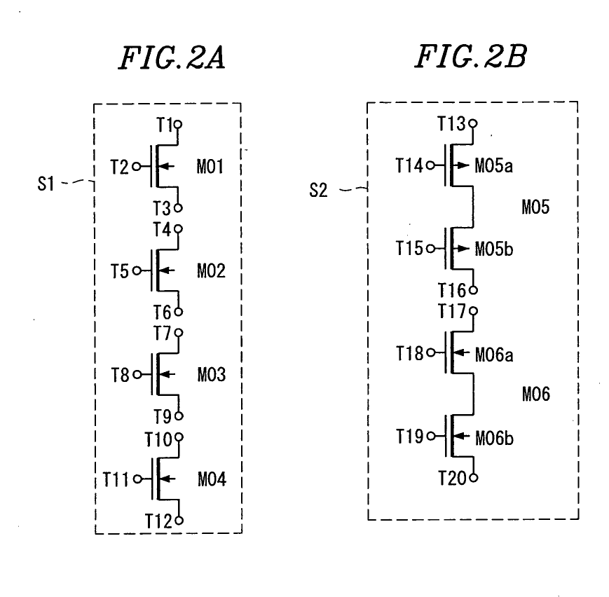

FIG. 1A is a layout diagram showing an exemplary cell pattern of a first cell S1 comprising a plurality of transistors constituting a pass transistor logic network which is used in a semiconductor integrated circuit according to Embodiment 1 of the present invention. FIG. 2A is a circuit diagram showing the first cell S1.

In FIGS. 1A and 2A, the first cell S1 comprises four NMOS transistors M01 to M04. The sources, drains, and gates of the NMOS transistors M01 to M04 are provided as terminals T1 to T12, respectively. The terminals T1 to T12 are connected with an upper metal wiring layer so as to obtain a desired pass logic circuit.

FIG. 1B is a layout diagram showing an exemplary cell pattern of a second cell S2 comprising two PMOS transistors connected in series and two NMOS transistors connected in series, which is used in fabrication of a semiconductor integrated circuit according to Embodiment 1 of the present invention. FIG. 2B is a circuit diagram of the second cell S2.

In FIGS. 1B and 2B, the second cell S2 comprises a PMOS transistor section M05 comprising a PMOS transistor M05a and M05b connected in series, and an NMOS transistor section M06 comprising NMOS transistors M06a and M06b connected in series. The sources and drains of the transistor sections M05 and M06 are connected in series and the gates of the transistors M05a, M05b, M06a and M06b are provided as terminals T13 to T20, respectively. The terminals T13 to T20 are connected in such a manner as to obtain a desired circuit, such as a buffering inverter circuit which is a driver circuit for driving a pass logic circuit, a circuit for constituting a DFF circuit (data flip-flop circuit) which is a data retaining circuit for retaining data output by a pass logic circuit, or the like.

As described above, the semiconductor integrated circuit of Embodiment 1 can be automatically designed and fabricated by an information processing apparatus within a computer performing the cell arrangement/wiring based on the standard cell scheme logic circuit synthesis control program.

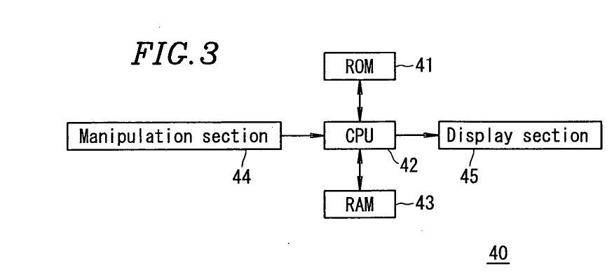

FIG. 3 is a block diagram showing a configuration of a computer system 40 for use in designing a semiconductor integrated circuit according to the present invention.

The computer system 40 comprises: a ROM 41 for storing a logic circuit synthesis control program; a CPU 42 (control section) for automatically synthesizing a desired logic circuit based on the logic circuit synthesis control program read out from the ROM 41; a RAM 43 used as a working memory by the CPU 42; a manipulation section 44 with which a manipulator enters a circuit specification, design constraints, or the like; and a display section 45 on which various screens, such as an manipulation entry screen or the like, are displayed.

In the standard cell scheme, a basic gate and a slightly complicated logic circuit comprising a combination of a plurality of basic gates are registered as standard cells in a cell library. The computer system 40 is used to combine standard cells for automatic synthesis of a desired logic circuit.

In the ROM 41, the input/output terminal positional information and operating rate information of standard cells, the arrangement information of transistors constituting a standard cell, and the like are registered in a cell library (a part of the ROM 41) in addition to the standard cell scheme logic circuit synthesis control program.

In Embodiment 1, the first cell S1 in which the terminals T1 to T12 in the transistors M01 to M04 are connected as shown in FIG. 2A and the second cell S2 in which the terminals T13 to T20 of the transistor sections M05 and M06 are connected as shown in FIG. 2B are registered as standard cells in the cell library.

The CPU 42 of FIG. 3 determines an arrangement of standard cells, a wiring pattern of conductors within and between the cells, and a width of a wiring channel (an interval between each cell array), based on the standard cell scheme logic circuit synthesis control program read out from the ROM 41, using various information in the cell library. In this case, the arrangement of cells, the wiring within and between the cells, and the wiring channel width are determined so that a circuit specification, design constraints, and the like input via the manipulation section 44 are satisfied and the total length of conductors within and between the cells are short. The thus determined arrangement pattern and wiring pattern of cells are transcribed onto a fabrication mask. The mask is used to fabricate conductors used in connections within and between cells. As a result, a semiconductor integrated circuit is produced.

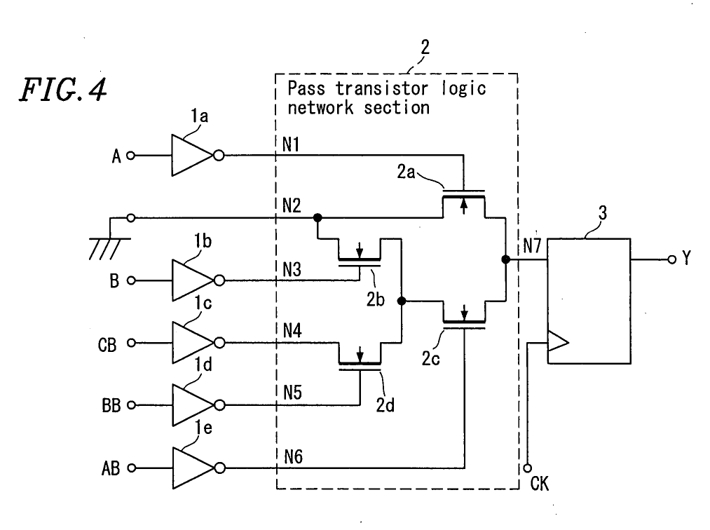

FIG. 4 is a circuit diagram showing an exemplary configuration of a semiconductor integrated circuit in which the first cell S1 is used to construct a logic operation circuit and the second cells S2 are used to construct a driver circuit for driving a pass transistor logic network, a data retaining circuit for retaining data, and the like.

In FIG. 4, the semiconductor integrated circuit has inverter buffer circuits 1a to 1e which are driver circuits for driving a pass transistor logic network; a pass transistor logic network circuit section 2; and a flip-flop circuit 3 which is a data retaining circuit for storing and retaining data output by the pass transistor logic network circuit 2.

Each of the inverter buffer circuits 1a to 1e is fabricated using the second cell S2 of FIG. 1B. The pass transistor logic network circuit section 2 is fabricated using the first cell S1 of FIG. 1A. The flip-flop circuit 3 is fabricated using a plurality of second cells S2 of FIG. 1B.

The pass transistor logic network circuit section 2 comprises four NMOS transistors 2a to 2d. The gate of the NMOS transistor 2a is connected to a node N1. The source of the NMOS transistor 2a is connected to a node N2. The drain of the NMOS transistor 2a is connected to a node N7. The gate of the NMOS transistor 2b is connected to a node N3. The source of the NMOS transistor 2b is connected to the node N2. The drain of the NMOS transistor 2b is connected to a series connection node between the NMOS transistors 2c and 2d. The gate of the NMOS transistor 2a is connected to a node N6. The source of the NMOS transistor 2c is connected to a parallel connection node between the NMOS transistors 2b and 2d. The drain of the NMOS transistor 2c is connected to the node N7. The gate of the NMOS transistor 2d is connected to a node N5. The source of the NMOS transistor 2d is connected to a node N4. The drain of the NMOS transistor 2d is connected to a series connection node between the NMOS transistors 2b and 2c.

The node N1 is connected to an input terminal A from which a signal A is input via the inverter buffer circuit 1a. The node N2 is connected to a ground voltage GND (Vss). The node N3 is connected to an input terminal B from which a signal B is input via the inverter buffer circuit 1b. The node N4 is connected to an input terminal CB from which a signal CB is input via the inverter buffer circuit 1a. The node N5 is connected to an input terminal BB from which a signal BB is input via the inverter buffer circuit 1d. The node N6 is connected to an input terminal AB from which a signal AB is input via the inverter buffer circuit 1e. Note that the suffix “B” of a signal represents an inverted signal. The node N7 is connected to a data input terminal of the flip-flop circuit 3. A clock signal CK is input to a clock input terminal of the flip-flop circuit 3. A result of a logic operation is output via an output terminal Y.

With this circuit, the operation of the following logical expression is achieved:

Y=A×B×C.

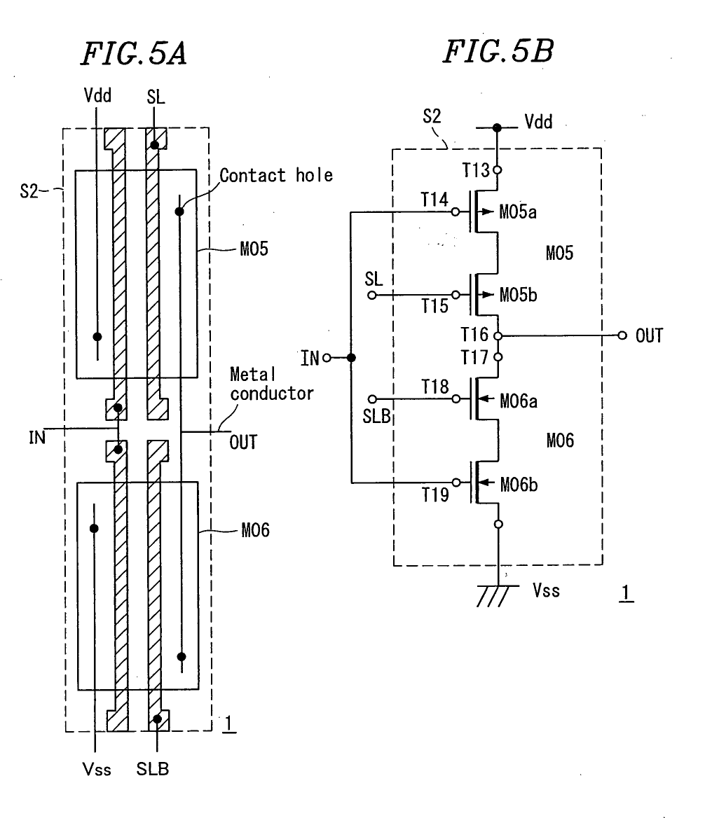

FIGS. 5A and 5B show examples of the inverter buffer circuits 1a to 1e of FIG. 4 which are obtained using the second cell S2 of FIG. 1B. FIG. 5A is a layout diagram showing a cell pattern and wiring pattern thereof and FIG. 5B is a circuit diagram showing a circuit configuration thereof.

In FIGS. 5A and 5B, the inverter buffer circuit 1 is constructed by connecting the terminals T13 to T20 of the transistor sections M05 and M06 constituting the second cell S2 with an upper metal wiring layer via contact holes for connecting each terminal and the metal wiring layer.

In the second cell S2, the source terminal T13 of the series connection PMOS transistor section M05 is connected to a first source voltage Vdd. The gate terminal T14 of the PMOS transistor M05a closer to the source is connected to an input terminal IN. The gate terminal T15 of the PMOS transistor M05b closer to the drain is connected to a control signal SL. The drain terminal T16 is connected to an output terminal OUT.

The source terminal of the series connection NMOS transistor M06 is connected to a second source voltage Vss (ground voltage GND). The gate terminal T19 of the NMOS transistor M06b closer to the source is connected to the input terminal IN. The gate terminal T18 of the NMOS transistor M06a closer to the drain is connected to a control signal SLB. The drain terminal T17 is connected to the output terminal OUT.

In a circuit operation, the control signal SL is set to “L”=Vss, while SLB is set to “H”=Vdd. In this case, the PMOS transistor M05b and the NMOS transistor M06a are in the “ON” state, so that the circuit functions as an inverter circuit which outputs an inverted signal for the input signal IN through the output terminal OUT. In a standby state, the control signal SL is “H”=Vdd, while the SLB is “L”=Vss. In this case, the PMOS transistor M05b and the NMOS transistor M06a are in the “OFF” state, so that the circuit is not achieved. Therefore, since the PMOS transistor M05b and the NMOS transistor M06a are in the “OFF” state, a penetrating path from the first source voltage Vdd to the second source voltage Vss is not generated irrespective of the potential of the input signal IN, thereby making it possible to reduce a consumed current.

Recently, micro-fabrication causes a problem such that an increase in leakage current when a transistor is in the “OFF” state leads to an increase in current consumption in the standby state. A solution to this problem according to the present invention will be described below.

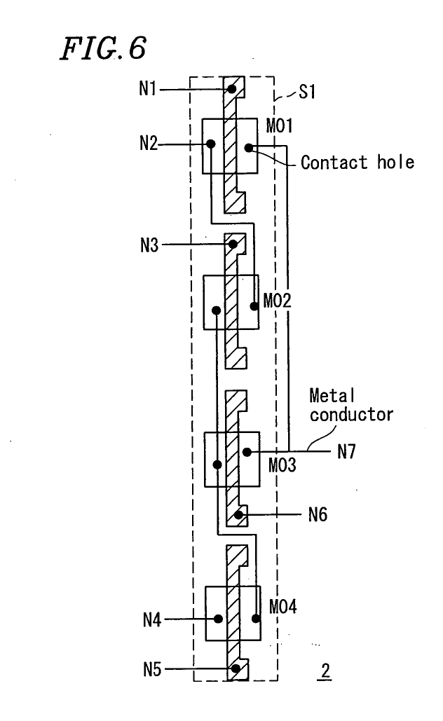

FIG. 6 is a layout diagram showing the cell pattern and wiring pattern of an example in which the first cell S1 of FIG. 1A isused to construct the pass transistor logic network section 2 of FIG. 4.

The pass transistor logic network section 2 is constructed by using one first cell S1 of FIG. 1A where the terminals T1 to T12 of the transistors M01 to M04 are connected to an upper metal wiring layer via contact holes for connecting terminals with the metal wiring layer.

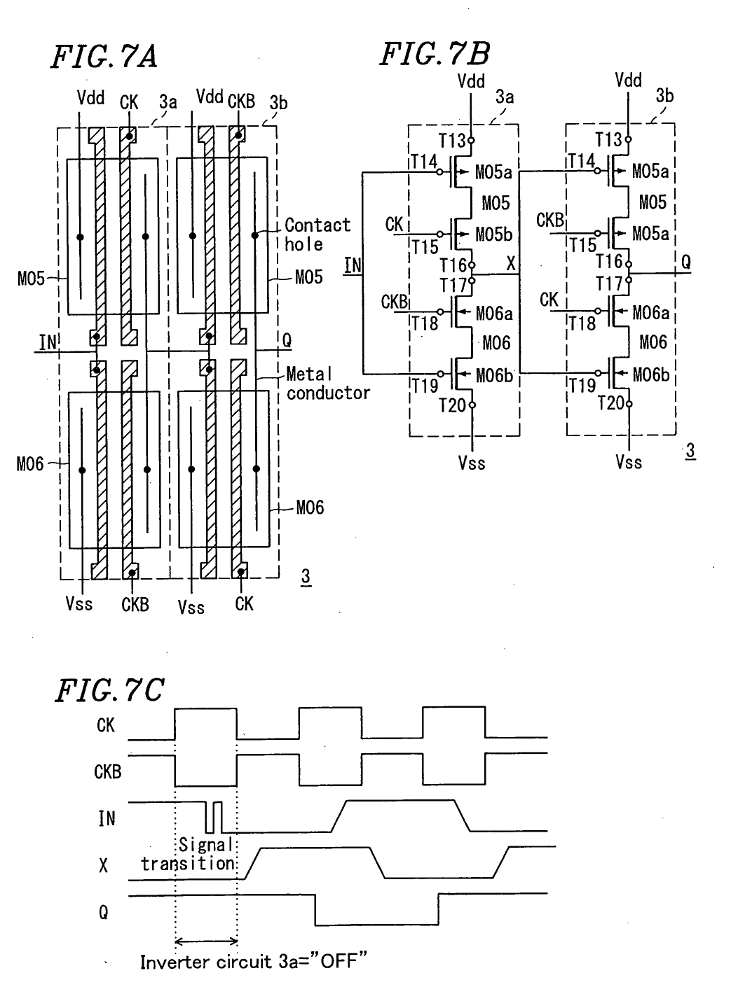

FIGS. 7A to 7C show an example of the flip-flop circuit 3 of FIG. 4 in which the second cell S2 of FIG. 1B is used. FIG. 7A is a layout diagram showing the cell pattern and wiring pattern thereof. FIG. 7B is a circuit diagram thereof. FIG. 7C is a timing chart showing an operating timing thereof.

In FIGS. 7A to 7C, the flip-flop circuit 3 is constructed by using two second cells S2 of FIG. 1B, where the terminals T13 to T20 of the transistor sections M05 and M06 are connected to an upper metal wiring layer via contact holes for connecting the terminals T13 to T20 with the metal wiring layer. Cells 3a and 3b are each inverter circuits having a gate control signal input terminal as in the inverter buffer circuit 1 of FIGS. 5A and 5B.

Here, a signal CK is input to the gate control signal input terminal T15 of the initial stage inverter circuit 3a, and a signal CKB which is an inverted signal of the signal CK is input to the gate control signal input terminal T18. The signal CKB is input to the gate control signal input terminal T15 of the subsequent stage inverter circuit 3b, and the signal CK is input to the gate control signal input terminal T18. The input signal IN of the flip-flop circuit 3 is input to the input terminals T14 and T19 of the initial stage inverter circuit 3a. An output X of the inverter circuit 3a is input to the input terminals T14 and T19 of the subsequent stage inverter circuit 3b. An output Q is output through the output terminals T16 and T17.

The flip-flop circuit 3 is of a dynamic type. As shown in FIG. 7C, when the signal CK is in the “L” level, the inverter circuit 3a is in the “ON” state and an inverted signal of input data is output. In this case, if the input signal IN is in the “L” level, the gate electrodes of the respective transistor M05a and M06b constituting the inverter circuit 3b connected to the node X of the input terminals T14 and T19 is charged to the “H” level with an output of the inverter circuit 3a. Next, when the signal CK goes to the “H” level, the inverter circuit 3b is turned into the “ON” state, so that an “L” signal is output through the output terminal Q. With a series of the above-described operations, the circuit functions as a DFF circuit (data-flip-flop circuit).

In the data flip-flop circuit (DFF circuit) 3 of FIGS. 7A to 7C, the gate control signals are input to the gate terminals of the transistors M05b and M06a closer to the drain, thereby achieving low power consumption. This mechanism will be described below with reference to the time chart of FIG. 7C.

Regarding the signal IN input to the flip-flop circuit 3, an output of the preceding stage DFF circuit in the pipeline operation is supplied to the input terminal through the inverter buffer circuits 1a to 1e and the pass transistor logic network section 2 as shown in FIG. 4. Therefore, the output data of the preceding stage DFF is output when the clock signal CK is changed to the “H” level. After the signal is passed through paths so that a pass transistor logic operation is performed, the signal IN input to the flip-flop circuit 3 is eventually determined to be in the “H” or “L” level. The signal IN may have an uncertain value due to the delay difference between each signal until it is eventually determined. The uncertain input signal leads to an increase in current consumption of the inverter circuit 3a. In Embodiment 1, however, when the clock signal CK is in the “H” level, the transistors M05b and M06a of the inverter circuit 3a are in the “OFF” state. When the signal IN is being transitioned, the inverter circuit 3a does not work. Therefore, unnecessary current consumption can be removed. Although FIGS. 7A to 7C show the exemplary configuration of the dynamic type flip-flop, a static type flip-flop can be constructed in a manner similar to that of the dynamic type.

As described above, according to Embodiment 1, two types of cell structures, i.e., the first cell S1 comprising a plurality of transistors constituting the pass transistor logic network section 2, and the second cell S2 comprising PMOS transistors connected in series and NMOS transistors connected in series, are prepared as standard cells within a library. By combining the standard cells, an arbitrary logic circuit can be easily obtained.

It is the inverter buffer circuits 1a to 1e and the inverter circuits 3a and 3b of the flip-flop circuit 3 that actually consume a current and generate a leakage current, but not the pass transistor logic network section 2. Therefore, in Embodiment 1, a circuit block which consumes current and generates a leakage current is fabricated using a second cell comprising transistors connected in series. A gate control signal is input to the gate electrode of one of the transistors connected in series so that the “ON” and “OFF” of the transistor are controlled. In this case, unnecessary current consumption and leakage current generation can be suppressed as described below.

(Embodiment 2)

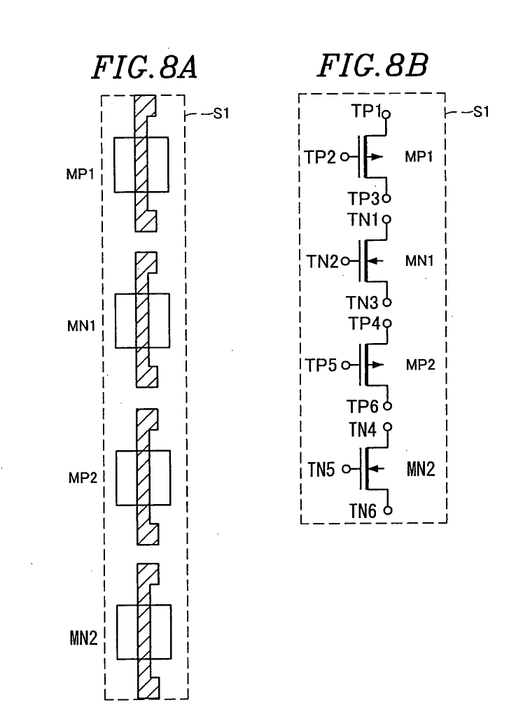

FIG. 8A is a pattern diagram showing an exemplary cell pattern of a first cell S1 comprising a plurality of transistors constituting a pass transistor logic network, which is used in a semiconductor integrated circuit according to Embodiment 2 of the present invention. FIG. 8B is a circuit diagram for explaining a configuration of the first cell S1.

In FIGS. 8A and 8B, the first cell S1 comprises two (a pair of) PMOS transistors MP1 and MP2 and two (a pair of) NMOS transistors MN1 and MN2.

Pass transistor logic circuits are often composed of only NMOS transistors. However, considering low voltage operations, which are increasingly demanded, a problem arises such that signal amplitude is lowered due to the NMOS single gate. To overcome this problem, a pass transistor network of a CMOS type in which a PMOS gate and an NMOS gate are complementarily used may be employed.

In Embodiment 2, in order to measure the above-described situation, one or more cells for a pass transistor logic network, each comprising a pair of an NMOS transistor and a PMOS transistor, are provided to form a logic circuit. The sources, drains, and gates of the PMOS transistors MP1 and MP2 are provided as terminals TP1 to TP6. The sources, drains, and gates of the NMOS transistors MN1 and MN2 are provided as terminals TN1 to TN6. The terminals TP1 to TP6 and TN1 to TN6 are connected via an upper metal wiring layer so as to obtain a desired pass logic circuit.

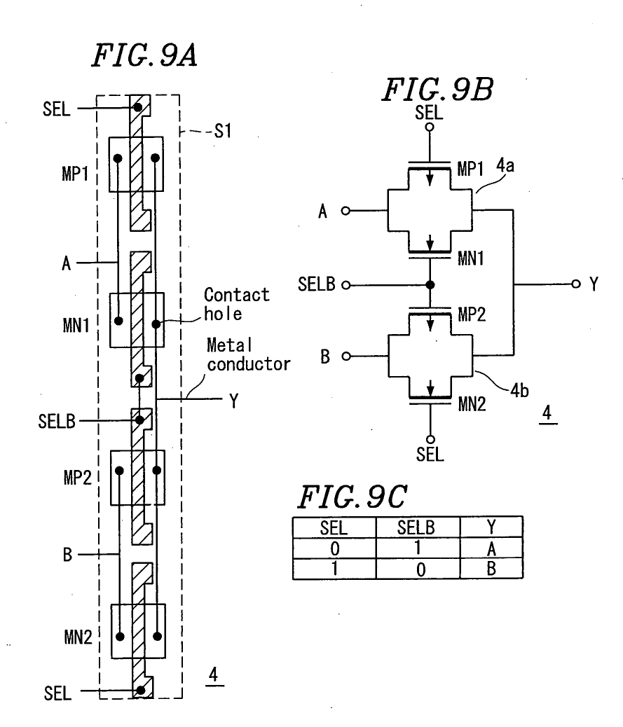

FIGS. 9A to 9C show an exemplary selector logic circuit 4 (logic operation circuit) which is constructed using the first cell S1 of FIGS. 8A and 8B. FIG. 9A is a layout diagram showing a cell pattern and wiring pattern thereof. FIG. 9B is a circuit diagram thereof. FIG. 9C is a table showing a relationship between input signals SEL and SELB and an output signal Y.

In FIGS. 9A to 9C, the selector logic circuit 4 is constructed by using one first cell S1 of FIGS. 8A and 8B, wherein the terminals TP1 to TP6 and TN1 to TN6 of the transistors MP1, MP2, MN1 and MN2 are connected to an upper metal wiring layer via contact holes for connecting the terminals with the metal wiring layer. The PMOS transistor MP1 whose gate receives the signal SEL and the NMOS transistor MN1 whose gate terminal receives the signal SELB are connected such that their sources are connected to each other and their drains are connected to each other. In this manner, a transfer gate 4a is constructed. The NMOS transistor MN2 whose gate receives the signal SEL and the PMOS transistor MP2 whose gate terminal receives the signal SELB are connected such that their sources are connected to each other and their drains are connected to each other. In this manner, a transfer gate 4b is constructed. The source of the transfer gate 4a is connected to an input terminal A which receives a signal A. The source of the transfer gate 4b is connected to an input terminal B which receives a signal B. The drains of the transfer gates 4a and 4b are commonly connected to an output terminal Y.

When the signal SEL is “0” and the signal SELB is “1”, the transfer gate 4a is turned into the “ON” state and the transfer gate 4b is turned into the “OFF” state. In this case, the signal A is output through the output terminal Y. When the signal SEL is “1” and the signal SELB is “0”, the transfer gate 4a is turned into the “OFF” state and the transfer gate 4b is turned into the “ON” state. In this case, the signal B is output through the output terminal Y.

Thus, by constructing a first cell S1 constituting a pass transistor logic network with both a PMOS transistor and an NMOS transistor, a CMOS type pass transistor logic circuit can be achieved. Particularly in the case of an SOI structure as described below, a well for a PMOS transistor and an NMOS transistor is not required. Thereby, a disadvantage of an increasing area when a CMOS type device is fabricated can be reduced.

(Embodiment 3)

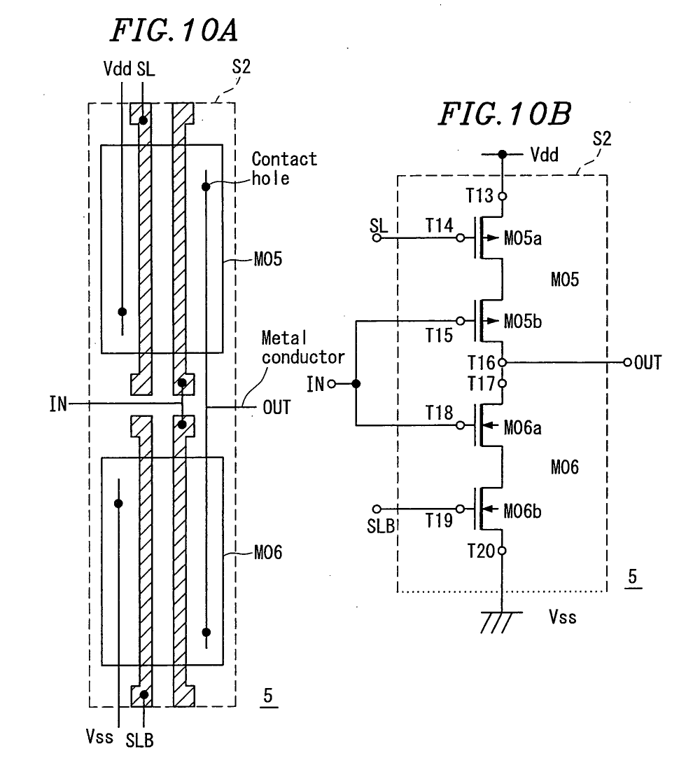

FIGS. 10A and 10B show a semiconductor integrated circuit according to Embodiment 3 of the present invention, in which the second cell S2 of FIG. 1B is used to construct an inverter circuit which constitutes a driver circuit for driving different pass transistor logic networks, a data retaining circuit for retaining data output from a pass transistor logic network, or the like. FIG. 10A is a layout diagram showing a cell pattern and wiring pattern thereof. FIG. 10B is a circuit diagram thereof. Note that the semiconductor integrated circuit has a connection structure different from that of the inverter buffer circuit 1 of FIGS. 5A and 5B.

In FIGS. 10A and 10B, the inverter circuit 5 is constructed by connecting the terminals T13 to T20 of transistor sections M05 and M06 constituting a second cell S2 to an upper metal wiring layer via contact holes for connecting the terminals and the metal wiring layer.

In the second cell S2, the source terminal T13 of the series connection PMOS transistor section M05 is connected to a first source voltage Vdd, and the gate terminal T15 of the PMOS transistor M05b closer to the drain is connected to an input terminal IN. The gate terminal T14 of the PMOS transistor M05a closer to the source is connected to the control signal SL. The drain terminal T16 is connected to an output terminal OUT.

The source terminal of the series connection NMOS transistor section M06 is connected to a second source voltage Vss (ground voltage GND). The gate terminal T18 of the NMOS transistor M06a closer to the drain is connected to the input terminal IN. The gate terminal T19 of the NMOS transistor M06b closer to the source is connected to the control signal SLB. The drain terminal T17 is connected to the output terminal OUT.

In a circuit operation, the control signal SL is set to “L”=Vss, while SLB is set to “H”=Vdd. In this case, the PMOS transistor MO5a and the NMOS transistor M06b are in the “ON” state, so that the circuit functions as an inverter circuit which outputs an inverted signal for the input signal IN through the output terminal OUT. In a standby state, the control signal SL is “H”=Vdd, while the SLB is “L”=Vss. In this case, the PMOS transistor M05a and the NMOS transistor M06b are in the “OFF” state, so that the circuit is not operated. Therefore, since the PMOS transistor M05a and the NMOS transistor M06b are in the “OFF” state, a penetrating path from the first source voltage Vdd to the second source voltage Vss is not generated irrespective of the potential of the input signal IN, thereby making it possible to reduce a consumed current.

In Embodiment 3, in the inverter circuit 5, the gate control signals are input to the gate terminals of the transistors M05a and M06b closer to the source. Thus, the transistors M05a and M06b closer to the source are used for gate control. Therefore, in an operation, the transistors M05a and M06b closer to the source voltage (source) are always in the “ON” state. Therefore, the sources of the transistors M05b and M06a, which are actually operated in response to the input signal IN, are charged to the source voltages Vdd and Vss. Thereby, a high-speed operation can be expected.

In Embodiments 1 and 3, a second cell comprising transistors connected in series is used to construct an inverter buffer circuit, an inverter circuit for a flip-flop circuit, or the like, which provides another advantage.

Recently, micro-fabrication techniques raise a problem that a leakage current is increased when a transistor is in the “OFF” state. This problem can be solved as follows. As in the inverter circuit 1 of Embodiment 1 in FIGS. 5A and 5B and the inverter circuit 5 of Embodiment 3 in FIGS. 10A and 10B, a second cell comprising PMOS transistors connected in series and NMOS transistors connected in series is used and the gate of one of the PMOS and NMOS transistors is used as a gate control signal input terminal and is controlled using a control signal. This mechanism will be described using the inverter circuit 5 of FIGS. 10A and 10B as an example.

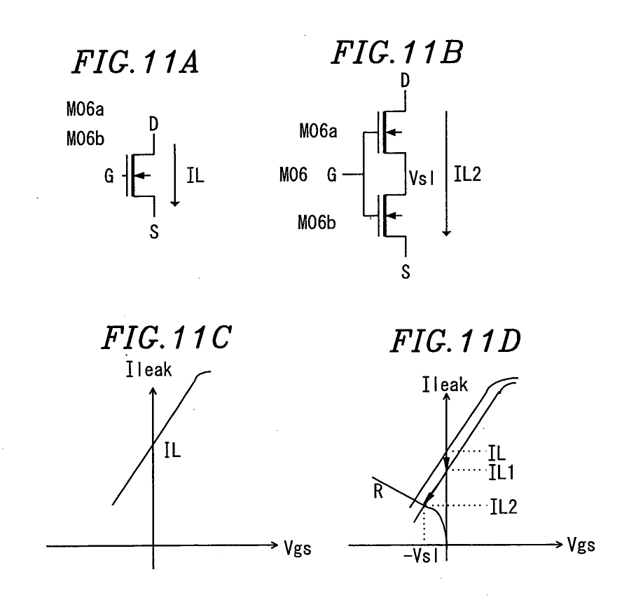

In the inverter circuit 5, when the control signal SL is “H” and SLB is “L” in the standby state, the transistors M05a and M06b are turned into the “OFF” state. Here, it is assumed that the input signal IN is at the “L” level. In this case, all of the transistors M05a, M06a and M06b are in the “OFF” state while the transistor M05b in a leakage path from a first source voltage Vdd of the inverter circuit 5 to a second source voltage Vss (GND) is in the “ON” state, thereby reducing a leakage current. In particular, the gates of the NMOS transistor section M06 closer to the second source voltage Vss have the same potential Vss and are in the “OFF” state. Here, the leakage current will be described with reference to FIGS. 11A to 11D.

The characteristics of a single transistor M06a or M06b shown in FIG. 11A are shown in a graph of FIG. 11C. Recent miniaturization of transistors and low threshold tend to increase leakage current. When Vss is applied to the gate electrode of a single transistor and the source potential is Vss, the gate-source voltage Vgs is zero and a current flowing between the drain and the source is IL.

In the transistor section M06 comprising the transistors M06a and M06b connected in series shown in FIG. 11B, a source-drain voltage is divided by the series connection. Therefore, as shown in FIG. 11B, the source potential of the transistor M06a is Vs1 and a leakage current is decreased to IL1 due to the substrate bias effect. In addition, the transistor M06b provides a load, and has load characteristics indicated by R in FIG. 11D. The gate potential of the transistor M06a is zero and the source potential thereof is Vs1, so that a gate-source voltage Vgs is −Vs1. Therefore, a leakage current flowing through the series connection transistor M06 is decreased to a current value IL2 which is obtained from an intersection between the characteristic curve and the load curve R of the transistor section M06b. Therefore, the leakage current value of the series connection transistor section M06 is IL2 which is considerably smaller than the leakage current value IL of a single transistor.

Thus, by using a second cell comprising transistors connected in series to construct an inverter circuit, for example, as shown in FIGS. 10A and 10B, a leakage current can be significantly reduced due to the effect of the series connection transistor.

On the other hand, when the input signal IN is in the “H” level, the gates of the PMOS transistors M05a and M05b connected in series are at the level of Vdd and the PMOS transistors MO5a and M05b are in the “OFF” state. In this case, as in the above-described NMOS transistor section M06, a leakage current can be significantly reduced due to the series connection structure. Thus, in the inverter circuit of FIGS. 10A and 10B, a leakage current in the standby state can be reduced no matter whether the input signal IN is in the “H” level or the “L” level.

Here, as shown in FIGS. 10A and 10B, the inverter circuit 5 has been described, in which the gate control signals are input to the gates of transistors of a series circuit closer to the source, and an input signal is input to a transistor of the series circuit closer to the drain. A leakage current can also be reduced in the inverter circuit 1 of Embodiment 1 in which the gate control signals are input to the gates of transistors closer to the drain and input signals are input to transistors closer to the source as shown in FIGS. 5A and 5B.

As described above, by using a series connection transistor in which gates are connected to the same potential, a leakage current can be reduced even when transistors having the same low threshold as that of other transistors are used. In this case, fabrication processes particularly provided for setting a plurality of thresholds is not required, thereby making it possible to achieve a semiconductor integrated circuit in which a leakage current can be reduced with low cost.

In addition, the “H” potential of the gate control signal supplied to the transistors connected in series may be designed to be higher than the first source voltage Vdd, while the “L” potential of the gate control signal may be designed to be lower than the second source voltage Vss. In this case, a leakage current can be further reduced. This mechanism will be described below with reference to the inverter circuit 5 of FIGS. 10A and 10B as an example.

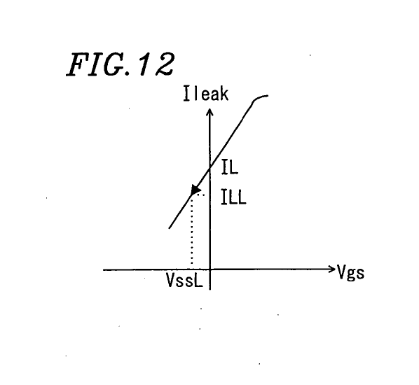

In the inverter circuit 5, the “L” level gate control signal SLB is input to the gate of the NMOS transistor M06b in the standby state. In this case, the transistor M06b is turned into the “OFF” state, so that a leakage current is reduced. Here, the ”L” level of the gate control signal SLB is designed to be Vs1 lower than Vss. In this case, the potential of the source is Vss, so that the gate-source voltage Vgs is a negative voltage VssL lower than Vss. As shown in FIG. 12, a leakage current is ILL which is lower than when the gate voltage is Vss.

Thus, by designing the gate-source voltage Vgs of the transistor to be at a negative potential, it is possible to reduce a leakage current. Similarly, for the PMOS transistor, a potential which is higher than the potential Vdd of the source is supplied to the gate, so that the gate-source voltage Vgs is at a negative potential, thereby making it possible to reduce a leakage current.

In the foregoing description of the inverter circuit 5 shown in FIGS. 10A and 10B, gate control signals are input to the gates of transistors of a series circuit closer to the sources (input side), while input signals are input to the transistors of the series circuit closer to the drains (output side). In the inverter circuit 1 shown in FIGS. 5A and 5B, a gate control signal is input to the gate of a transistor closer to the drain, while an input signal is input to a transistor closer to the source. Also in this case, a leakage current can be similarly reduced.

(Embodiment 4)

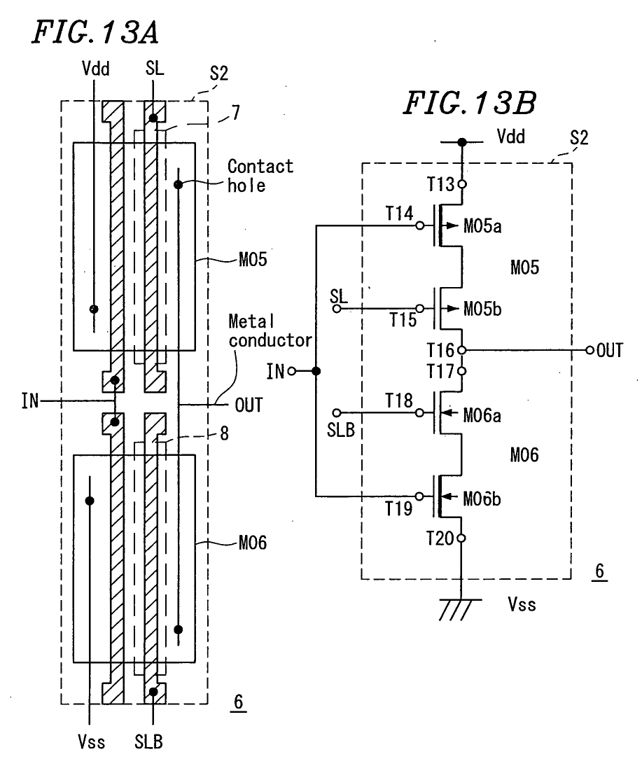

A semiconductor integrated circuit according to Embodiment 4 of the present invention has the same structure as that in Embodiment 1 or 3, where one of transistors connected in series has a higher threshold than that of the other transistor, thereby making it possible to further reduce a leakage current. An exemplary circuit structure of the semiconductor integrated circuit of Embodiment 4 will be described with reference to FIGS. 13A and 13B.

FIGS. 13A and 13B show the semiconductor integrated circuit according to Embodiment 4 of the present invention. Here, the second cell S2 of FIG. 1B is used to construct an inverter circuit 6 comprising a driver circuit for driving a pass transistor logic network, a data retaining circuit for retaining data output by the pass transistor logic network, or the like. FIG. 13A is a layout diagram showing a cell pattern and wiring pattern thereof. FIG. 13B is a circuit diagram thereof. The principle of operation of the inverter circuit 6 is similar to that of the inverter circuit 1 of FIGS. 5A and 5B.

In FIG. 13A, a mask pattern 7 is used to establish a high threshold of a PMOS transistor M05b, and a mask pattern 8 is used to establish a high threshold of the NMOS transistor M06a. In the inverter circuit 6, the transistors M05b and M06a are high threshold transistors which receive gate control signals SL and SLB, respectively. Therefore, in the standby state, the transistors M05b and M06a are in the “OFF” state, thereby reducing a leakage current. An OFF leakage current of a transistor is reduced by increasing the threshold voltage. Therefore, by using high threshold transistors as the transistors M05b and M06a, a leakage current in the standby state can be further reduced as compared to when low threshold transistors are used.

(Embodiment 5)

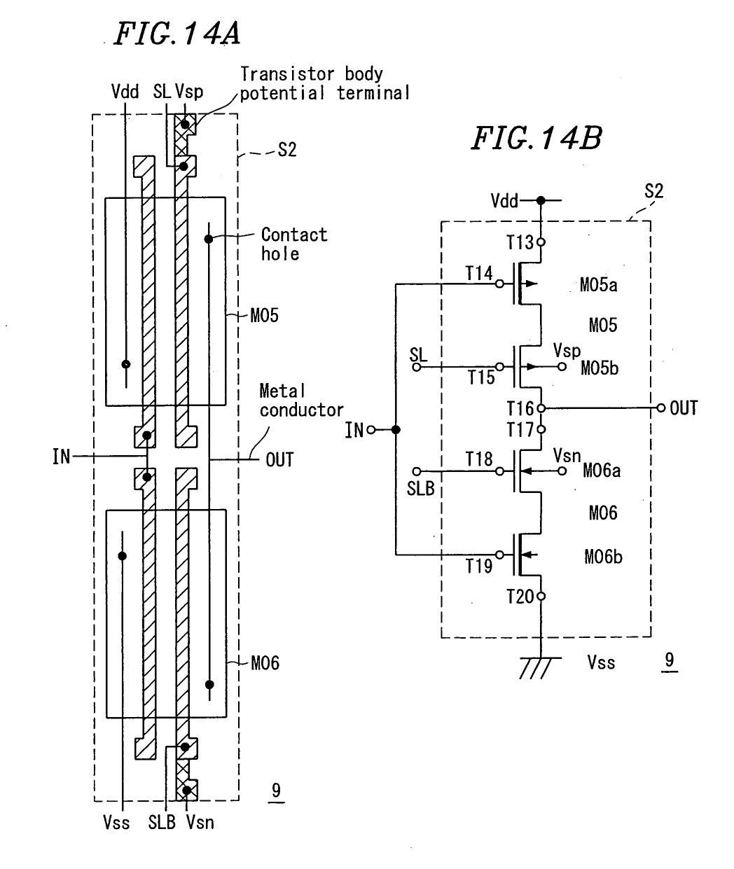

A semiconductor integrated circuit according to Embodiment 5 of the present invention has the same structure as that in Embodiment 1 , 3, or 4, where one of transistors connected in series is provided with a body potential terminal and a body potential can be controlled via the body potential terminal, thereby making it possible to further reduce a leakage current. An exemplary circuit structure of the semiconductor integrated circuit of Embodiment 5 will be described with reference to FIGS. 14A and 14B.

FIGS. 14A and 14B show the semiconductor integrated circuit according to Embodiment 5 of the present invention. Here, the second cell S2 of FIG. 1B is used to construct an inverter circuit 9 comprising a driver circuit for driving a pass transistor logic network, a data retaining circuit for retaining data output by the pass transistor logic network, or the like. FIG. 14A is a layout diagram showing a cell pattern and wiring pattern thereof. FIG. 14B is a circuit diagram thereof. The principle of operation of the inverter circuit 9 is similar to that of the inverter circuit 6 of FIGS. 13A and 13B.

In the inverter circuit 9, the high threshold transistors M05b and M06a of FIGS. 13A and 13B are provided with a body potential terminal so that body potentials Vsp and Vsn can be controlled, thereby making it possible to control a threshold voltage.

During the normal operation, SL=“L”, SLB=“H”, the body potential Vsp of the PMOS transistor M05b=Vdd, the body potential Vsn of the NMOS transistor M06a=Vss, and the transistors M05a and M06b have a normal threshold voltage. Therefore, the inverter circuit 9 performs a normal operation, and the body potential control transistors M05b and M06a are also operated with the same threshold voltage as that of the other transistors M05a and M06b.

In the standby state, SL=“H”, SLB=“L”, and the transistors M05b and M06a are in the “OFF” state. In this case, the body potential Vsp is designed to be Vdd+α (i.e., higher than Vdd) and the body potential Vsn is designed to be Vss−α (i.e.,lower than Vss). Thereby, the threshold voltage of the transistors M05b and M06a is increased. As a result, a leakage current can be further reduced.

(Embodiment 6)

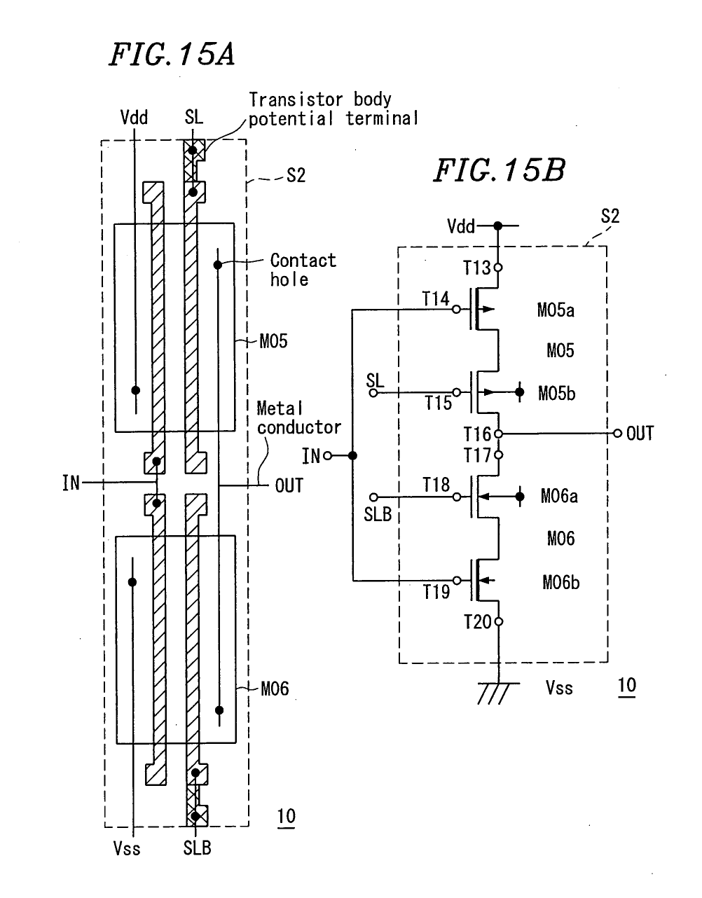

A semiconductor integrated circuit according to Embodiment 6 of the present invention has the same structure as that in Embodiment 1, 3 or 4, where one of transistors connected in series is a transistor to which a gate electrode and a body electrode are connected, thereby making it possible to further reduce a leakage current. An exemplary circuit structure of the semiconductor integrated circuit of Embodiment 6 will be described with reference to FIGS. 15A and 15B.

FIGS. 15A and 15B show the semiconductor integrated circuit according to Embodiment 6 of the present invention. Here, the second cell S2 of FIG. 1B is used to construct an inverter circuit 10 comprising a driver circuit for driving a pass transistor logic network, a data retaining circuit for retaining data output by the pass transistor logic network, or the like. FIG. 15A is a layout diagram showing a cell pattern and wiring pattern thereof. FIG. 15B is a circuit diagram thereof. The principle of operation of the inverter circuit 10 is similar to that of the inverter circuit 9 of FIGS. 14A and 14B.

In the inverter circuit 10 of FIGS. 15A and 15B, the body electrode and gate electrode are connected together for each of the transistors MO5b and M06a which are provided with the body potential terminal of FIGS. 14A and 14B.

By connecting the body and gate of a transistor in the above-described manner, the gate is biased so that a channel is formed while the body region is forward biased with respect to the source. Therefore, the threshold voltage is reduced. In order to reduce an OFF leakage current, a transistor may be designed to have a high threshold voltage. When such a transistor is operated, the threshold voltage is reduced so that a saturated current value is increased. Therefore, a high-speed operation can be achieved.

During the normal operation, SL=“L”, SLB=“H”, and the threshold voltages of the transistors M05a and M06b are reduced, so that a high-speed operation is achieved. In the standby state, SL=“H”, SLB=“L”, and the transistors M05b and M06a are in the “OFF” state. In this case, the threshold voltage of each of the transistors M05b and M06a is higher than when they are operated, leading to a reduction in leakage current.

In Embodiments 4, 5 and 6, the inverter circuit 1 as shown in FIGS. 5A and 5B is described, in which a gate control signal is input to the gate of a transistor closer to the drain, while an input signal is input to a transistor closer to the source. For the inverter circuit 5 of FIGS. 10A and 10B in which a gate control signal is input to the gate of a transistor closer to the source, while an input signal is input to a transistor closer to the drain, a leakage current can be similarly reduced by using a high threshold transistor, a transistor in which a body potential terminal is provided so as to control the body potential, and a transistor in which the body electrode and the gate electrode are connected together.

(Embodiment 7)

In Embodiment 1 of FIGS. 7A to 7C, a second cell comprising transistors connected in series is used to achieve a dynamic type DFF circuit as an example. In Embodiment 7, a static type data latch circuit will be described as an exemplary static type circuit which is achieved by using a second cell.

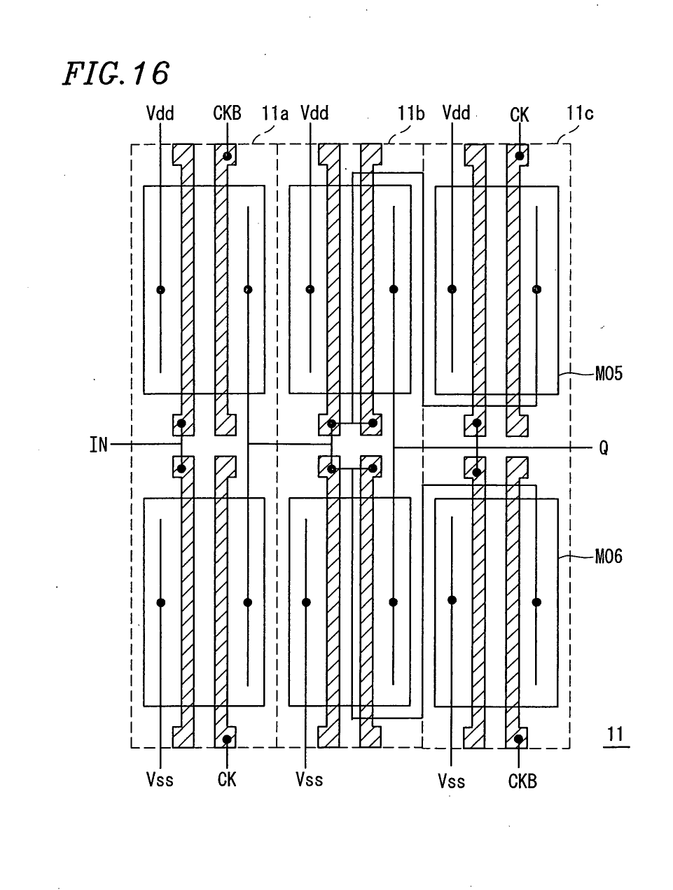

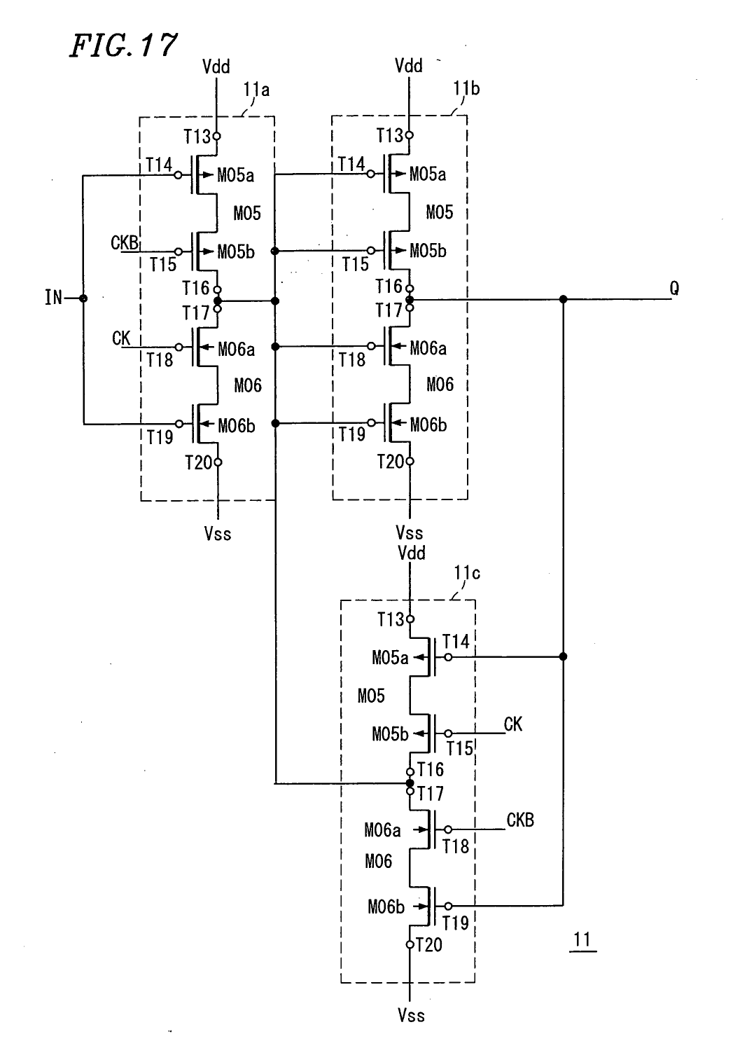

FIG. 16 is a layout diagram showing a semiconductor integrated circuit according to Embodiment 7 of the present invention which is a data latch circuit 11 constructed by using the second cell S2 of FIG. 1B, indicating a cell pattern and wiring pattern thereof. FIG. 17 is a circuit diagram of the data latch circuit 11.

In FIGS. 16 and 17, the data latch circuit 11 comprises three second cells S2 as shown in FIG. 1B, where the terminals T13 to T20 of the respective transistor sections M05 and M06 are connected to an upper metal wiring layer via contact holes for connecting the terminals and the metal wiring layer. The cells 11a to 11c are inverter circuits. A static operation is achieved by the feedback inverter circuit 11c.

The inverter circuit 11a receives a CKB signal (an inverted signal of CK) through a gate control signal input terminal T15 and a CK signal through a gate control signal input terminal T18. Also, an input signal IN is input to the input terminals T14 and T19 of the inverter circuit 11a. Input terminals T14, T15, T18, and T19 of the inverter circuit 11b are connected to output terminals T16 and T17 of the inverter circuit 11a and output terminals T16 and T17 of the inverter circuit 11c. The output terminals T16 and T17 of the inverter circuit 11b are connected to input terminals. T14 and T19 of the inverter circuit 11c and a signal output terminal Q. The inverter circuit 11c receives the CK signal through a gate control signal input terminal T15 and the CKB signal through a gate control signal input terminal T18.

In the data latch circuit 11, when the CK signal is at the “H” level and the CKB signal is at the “L” level, the inverter circuits 11a and 11b are operated and the inverter circuit 11c is in the “OFF” state. In this case, the input signal IN is output from the output terminal Q through the inverter circuits 11a and 11b. Next, when the CK signal goes to the “L” level and the CKB signal goes to the “H” level, the input stage inverter circuit 11a is turned into the “OFF” state and the subsequent stage feedback inverter circuit 11c is turned into the “ON” state so that a data retaining operation is performed.

In this case, the initial stage inverter circuit 11a which is in the “OFF” state has a reduced leakage current due to the transistor sections M05 and M06 connected in series as described in FIGS. 11A to 11D. By expanding the amplitudes of the CK signal and the CKB signal into the range from a potential higher than Vdd to a potential lower than Vss as described with reference to FIG. 12, a leakage current is further reduced. By designing the inverter circuit 11a or the inverter circuits 11a and 11b to have one of the structures shown in FIGS. 13A and 13B to 15A and 15B, a leakage current can be further reduced.

The inverter circuit 11b is always in the operating state. The gates of the transistors M05a, MO5b, M06a, and M06b connected in series are all input terminals. Therefore, if an input is in the “L” level, the series connection NMOS transistor section M06 is in the ”OFF” state, whereby a leakage current is reduced as described with reference to FIGS. 11A to 11D. If an input is in the “H” level, the series connection PMOS transistor section M05 is in the “OFF” state, where by a leakage current is similarly reduced.

In Embodiment 7, the feedback inverter circuit 11c is in the “ON” state in the standby state and the data retaining state. Therefore, the feedback inverter circuit 11a does not have a leakage current reducing function and has a leakage current.

(Embodiment 8)

In Embodiments 1 and 3 to 7, only the second cell S2 comprising transistors connected in series is used to construct a driver circuit for driving a pass transistor logic network, a data retaining circuit for retaining data output by the pass transistor logic network, or the like. In the present invention, the first cell S1 constituting a pass transistor logic network is prepared and the first and second cells S1 and S2 can be used to construct more varied circuits. In Embodiment 8, a second cell having transistors connected in series and a first cell constituting a pass transistor logic network are used to construct a data latch circuit which has a reduced leakage current.

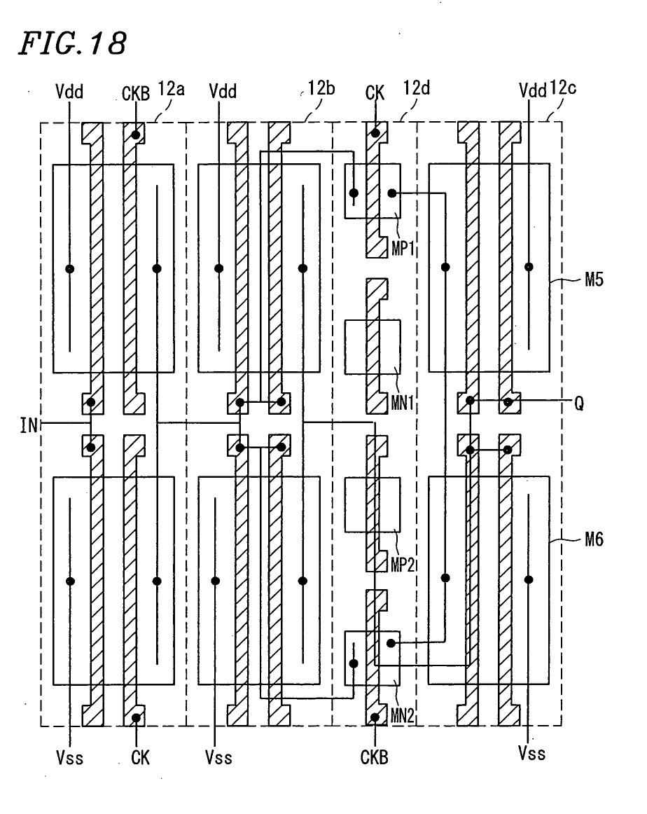

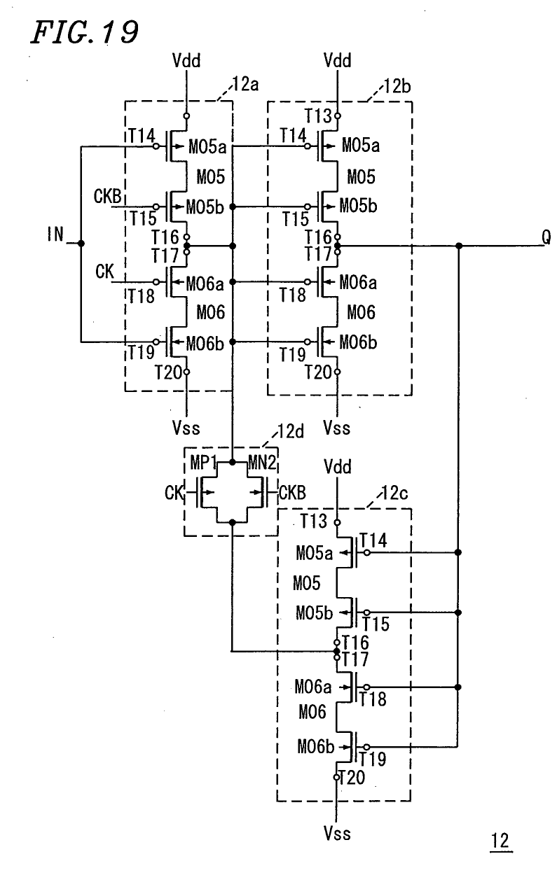

FIG. 18 is a layout diagram showing a cell pattern and wiring pattern of a semiconductor integrated circuit according to Embodiment 8 of the present invention, which is a data latch circuit 12 constructed by using the first cell S1 of FIG. 8A and the second cell S2 of FIG. 1B. FIG. 19 is a circuit diagram of the semiconductor integrated circuit of FIG. 18.

The data latch circuit 12 comprises: one single first cell S1 of FIG. 8A; three second cells S2 of FIG. 1B; the terminals TP1 to TP6 and TN1 to TN6 of the transistors MP1, MN1, MP2 and MN2 of the first cell S1; the terminals T13 to T20 of the respective transistor sections M05 and M06 of the second cells S2; an upper metal wiring layer; and contact holes for connecting the terminals with the metal wiring layer. The cells 12a to 12c are inverter circuits and the cell 12d is a transfer gate. In the data latch circuit 12, a static operation is caused by the feedback inverter circuit 12c, and a feedback operation is controlled by the transfer gate 12d.

In the inverter circuit 12a, a CKB signal (an inverted signal of CK) is input through the gate control signal input terminal T15, and a CK signal is input through the gate control signal input terminal T18. Also, an input signal IN is input through the input terminals T14 and T19 of the inverter circuit 12a. The input terminals T14, T15, T18, and T19 of the inverter circuit 12b are connected to the output terminals T16 and T17 of the inverter circuit 12a, and via the transfer gate 12d to the output terminals T16 and T17 of the inverter circuit 12c. The output terminals T16 and T17 of the inverter circuit 12b are connected to the input terminals T14, T15, T18, and T19 of the inverter circuit 12c and a signal output terminal Q.

In the data latch circuit 12, when the CK signal is at the “H” level and the CKB signal is at the “L” level, the inverter circuits 12a to 12c are operated and the transfer gate 12d is in the “OFF” state. In this case, the input signal IN is output via the inverter circuit 12a and 12b from the output terminal Q. Next, when the CK signal is at the “L” level and the CKB signal is at the “H” level, the input stage inverter circuit 12a is in the “OFF” state and the transfer gate 12d which performs feedback control is in the “ON” state, so that a data retaining operation is performed.

In this case, the initial stage inverter circuit 12a which is in the “OFF” state has a reduced leakage current due to the transistor sections M05 and M06 connected in series as described with reference to FIGS. 11A to 11D.

The inverter circuits 12b and 12c are always in the operating state. The gates of the transistors M05a, M05b, M06a, and M06b connected in series are input terminals. Therefore, when an input is at the “L” level, in the inverter circuit 12b the series connection NMOS transistor section M06 is in the “OFF” state, and in the inverter circuit 12c the series connection PMOS transistor section MOS is in the “OFF” state, whereby a leakage current is reduced, as described with reference to FIGS. 11A to 11D. When an input is at the “H” level, in the inverter circuit 12b the series connection PMOS transistor section M05 is in the “OFF” state, and in the inverter circuit 12a the NMOS transistor section M06 is in the “OFF” state, whereby a leakage current is similarly reduced.

By expanding the amplitudes of the CK signal and the CKB signal input to the initial stage inverter circuit 12a into the range from a potential higher than Vdd to a potential lower than Vss, a leakage current can be further reduced as described in FIG. 12. Alternatively, by designing the inverter circuits 12a to 12c to have the structure as shown in FIGS. 13A and 13B to 15A and 15B, a leakage current can be further reduced.

As described above, in Embodiment 8, a leakage current can be reduced in all the inverter circuits 12a to 12c. The leakage current can be further reduced as compared to the data latch circuit 11 of Embodiment 7 in FIG. 17. By expanding the amplitude of the CK signal input to the transfer gate 12d for controlling a feedback operation into the range from a potential higher than Vdd to a potential lower than Vss as in the inverter circuit 12a, a leakage current can be reduced, as described in FIG. 12. By constructing the transfer gate 12d using a high threshold transistor, a leakage current can be further reduced.

(Embodiment 9)

A semiconductor integrated circuit according to Embodiment 9 of the present invention is fabricated using a circuit as described in Embodiments 1 to 8, where only an active circuit block is operated while an inactive circuit block is in the standby state (stop state), thereby reducing power consumption.

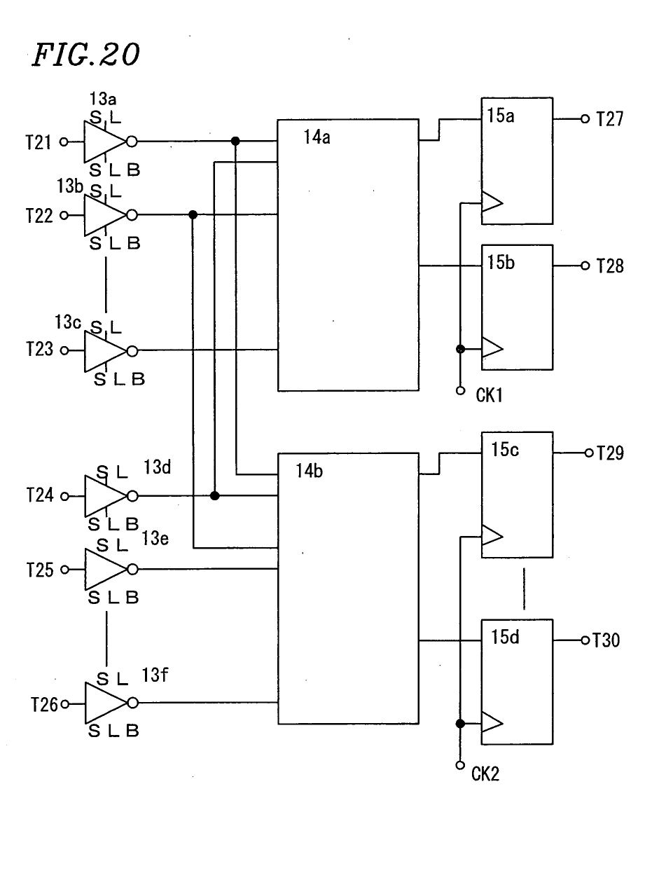

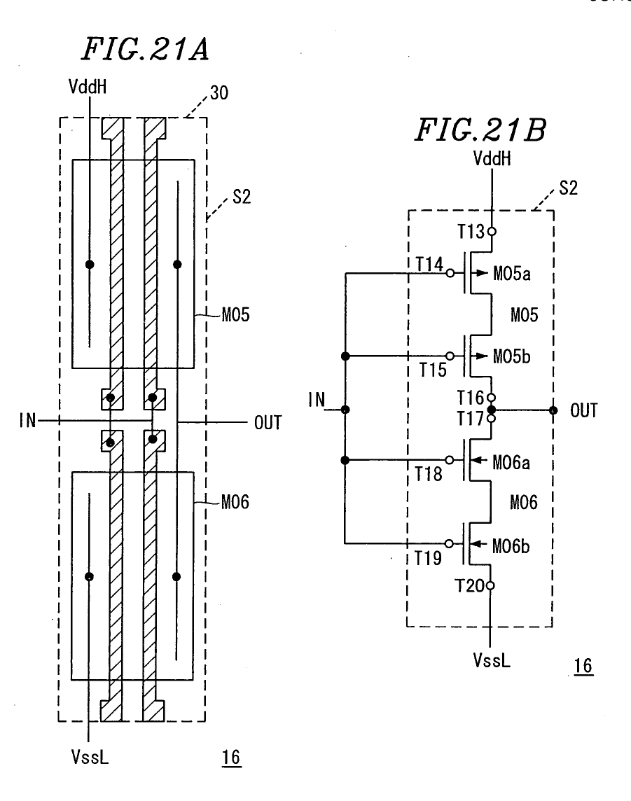

FIG. 20 is a circuit diagram showing a semiconductor integrated circuit according to Embodiment 9 of the present invention.

In FIG. 20, the semiconductor integrated circuit comprises: input terminals T21 to T26; inverter buffer circuits 13a to 13f having gate control signal input terminals; pass transistor logic circuit blocks 14a and 14b; data retaining circuits 15a to 15d for retaining an output signal; and output terminals T27 to T30.

The inverter buffer circuits 13a to 13f are constructed using a second cell (FIG. 1B) having PMOS transistors connected in series and NMOS transistors connected in series as described in Embodiments 1 to 8. The operating mode and standby mode of the inverter buffer circuits 13a to 13f are controlled using signals SL and SLB input through gate control signal input terminals thereof so that a leakage current in the standby state can be reduced.

The pass transistor logic circuit blocks 14a and 14b have a desired logic operating function which is designed using several first cells comprising a plurality of NMOS transistors (FIG. 1A) or an NMOS transistor and PMOS transistor pair (FIG. 8A) as described in Embodiments 1 to 8.

As described in each embodiment, the data retaining circuits 15a to 15d comprise a flip-flop circuit, a latch circuit, and the like which are constructed using a second cell (FIG. 1B) having PMOS transistors connected in series and NMOS transistors connected in series. The data retaining circuits 15a to 15d have a function such that when signals CK1 and CK2 are stopped, data can be retained while a leakage current is reduced.

In the semiconductor integrated circuit of Embodiment 9, when all the pass transistor logic circuit blocks 14a and 14b are operated, all circuits are in the operating state.

When only the logic operation of the pass transistor logic circuit block 14a is performed and the logic operation of the pass transistor logic circuit block 14b is not performed, data is input only to the pass transistor logic circuit block 14a and only outputs from the pass transistor logic circuit block 14a are retained.

Therefore, the inverter buffer circuits 13a to 13d, which supply a signal to the pass transistor logic circuit block 14a, are controlled using control signals SEL and SELB so as to be turned into the operating state. The inverter buffer circuits 13e and 13f, which do not supply a signal to the pass transistor logic circuit block 14a, are controlled using control signals SEL and SELB so as to be turned into the standby state. In this case, the inverter buffer circuits 13e and 13f in the standby state have a reduced leakage current as described in Embodiments 1 to 8.

The CK signal (CK1) is input only to the data retaining circuits 15a and 15b which are connected to an output of the pass transistor logic circuit block 14a, so that the data retaining circuits 15a and 15b are operated. The CK signal (CK2) of the data retaining circuits 15c and 15d, which are not connected to an output of the pass transistor logic circuit block 14a, is stopped. In this case, the data retaining circuits 15c and 15d retain data during a time when the CK signal is stopped as described in Embodiments 1 to 8, so that a leakage current is reduced therein.

In this case, only the pass transistor logic circuit block 14b does not consume a current. With the above-described structure, only a circuit section required for the logic operation of the pass transistor logic circuit block 14a is operated, while the other sections are not operated, whereby a leakage current is reduced, i.e., power is not wasted so that power consumption can be reduced.

Similarly, when only the logic operating function of the pass transistor logic operation block 14b is performed while the logic operating function of the pass transistor logic operation block 14a is not performed, data is input only to the pass transistor logic circuit block 14b and only data output from the pass transistor logic circuit block 14b is retained.

Therefore, the inverter buffer circuits 13a, 13b and 13d to 13f, which supply a signal to the pass transistor logic circuit block 14b, are controlled using the control signals SEL and SELB so as to be turned into the operating state. The inverter buffer circuit 13a, which does not supply a signal to the pass transistor logic circuit block 14b, is controlled using the control signals SEL and SELB so as to be turned into the standby state. In this case, the inverter buffer circuit 13a in the standby state has a reduced leakage current as described in Embodiments 1 to 8.

The CK signal (CK2) is input only to the data retaining circuits 15a and 15d which are connected to an output of the pass transistor logic circuit block 14b, so that the data retaining circuits 15c and 15d are operated. The CK signal (CK1) of the data retaining circuits 15a and 15b, which are not connected to an output of the pass transistor logic circuit block 14b, is stopped. In this case, the data retaining circuits 15a and 15b retain data during a time when the CK signal is stopped as described in Embodiments 1 to 8, so that a leakage current is reduced therein.

In this case, only the pass transistor logic circuit block 14a does not consume a current. With the above-described structure, only a circuit section required for the logic operation of the pass transistor logic circuit block 14b is operated, while the other sections are not operated, whereby a leakage current is reduced, i.e.,power is not wasted so that power consumption can be reduced.

When the circuit is in the standby state, the inverter buffer circuit and the data retaining circuit are in the standby state (stop state). Therefore, current consumption can be reduced and a leakage current can be reduced.

Thus, by using a first cell comprising a plurality of transistors constituting a pass transistor logic network and a second cell comprising PMOS transistors connected in series and NMOS transistors connected in series to construct a semiconductor integrated circuit, only required portions are operated and a leakage current is reduced in the other portions, thereby making it possible to easily obtain a semiconductor integrated circuit having low power consumption and substantially no wasted power consumption.

In addition, by expanding the signal amplitudes of the gate control signals SEL, SELB and the clock signals CK1 and CK2 input to the circuit into the range from a potential higher than Vdd to a potential lower than Vss, a leakage current can be further reduced.

(Embodiment 10)

In Embodiments 7 to 9, a leakage current can be reduced by expanding the signal amplitudes of the gate control signals SEL, SELB and the clock signal CK1 and CK2 input to the circuit into the range from a potential higher than Vdd to a potential lower than Vss. In this case, an expanded voltage is applied to a driver circuit for driving a signal having a broader amplitude than a source voltage. Therefore, a problem arises in source-drain voltage resistance in current devices having an advanced level of microstructure. In Embodiment 10, a driver circuit is constructed by using an inverter circuit having a second cell comprising PMOS transistors connected in series and NMOS transistors connected in series, where the gates of transistors constituting the series connection transistors are connected together.

FIGS. 21A and 21B show a semiconductor integrated circuit according to Embodiment 10 of the present invention, where the second cell S2 of FIG. 1B is used to construct an inverter circuit 16 which is used as a driver circuit. FIG. 21A is a layout diagram showing a cell pattern and wiring pattern thereof. FIG. 21B is a circuit diagram thereof.

In FIGS. 21A and 21B, the inverter circuit 16 is constructed by connecting the terminals T13 to T20 of the transistor sections M05 and M06 constituting the second cell S2 of FIG. 1B to an upper metal wiring layer via contact holes for connecting the terminals and the metal wiring layer. The gates of the transistors M05a, M05b, M06a, and M06b are connected together and an input signal IN is input to the gates.

Thus, by connecting all the gates of the transistors together, a voltage applied to the series connection transistor sections M05 and M06 comprising the transistors M05a, M05b, M06a, and M06b are divided into voltages applied to the transistors M05a, M05b, M06a, and M06b. Thereby, a voltage which is actually applied to each transistor is lower than a source voltage. Therefore, the voltage resistance of the series connection transistor is improved. Thus, according to Embodiment 10, it is possible to achieve a driver circuit to which a signal having a higher voltage can be applied.

(Embodiment 11)

In Embodiments 1 to 10, transistors may have a SOI (Silicon on Insulator) structure. In this case, a semiconductor integrated circuit can have a lower power consumption. In Embodiment 11, a semiconductor integrated circuit comprises an SOI-structure transistor will be described.

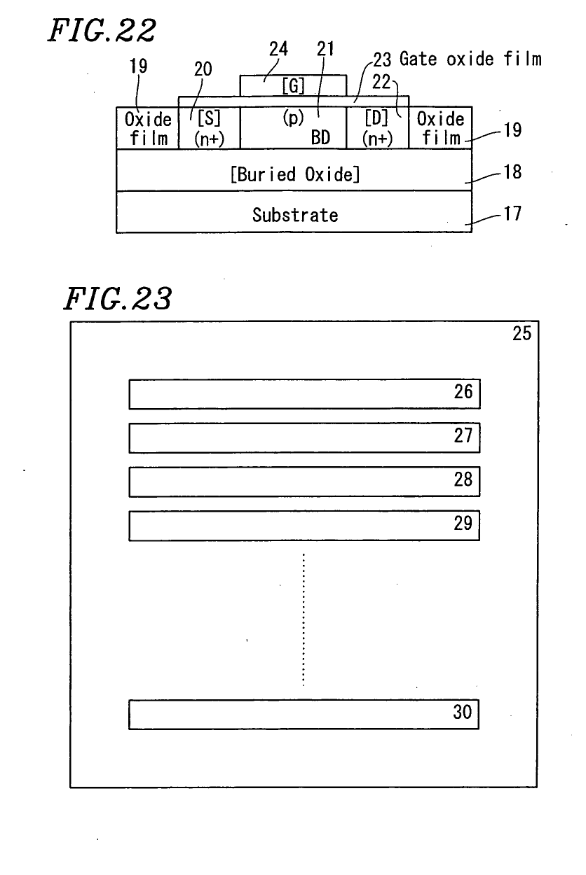

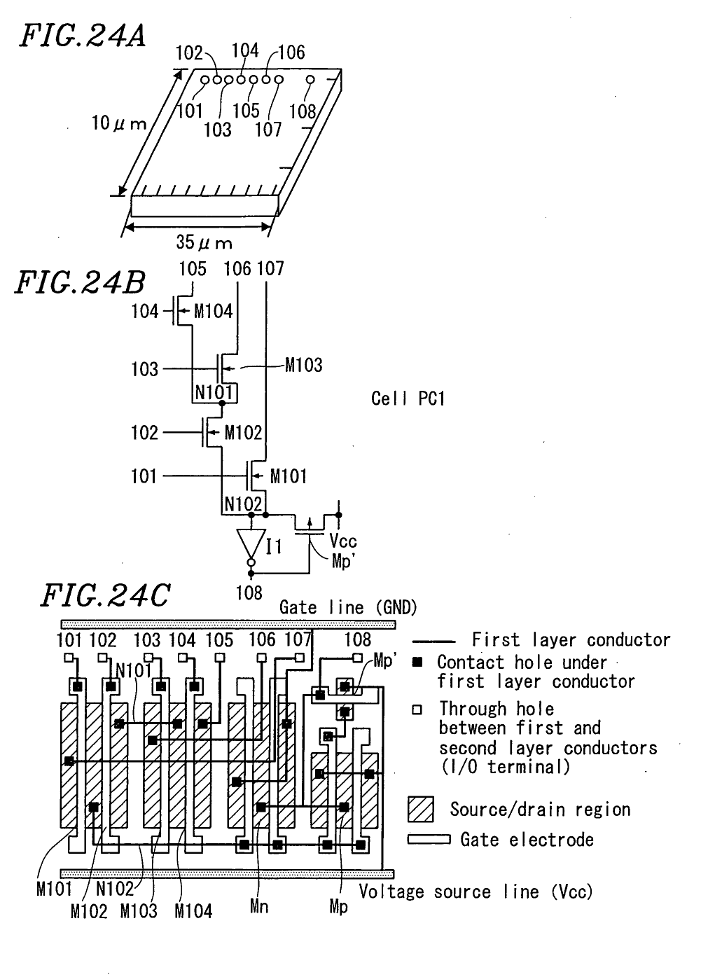

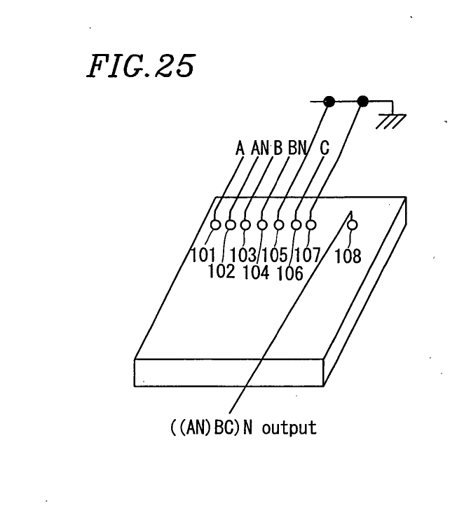

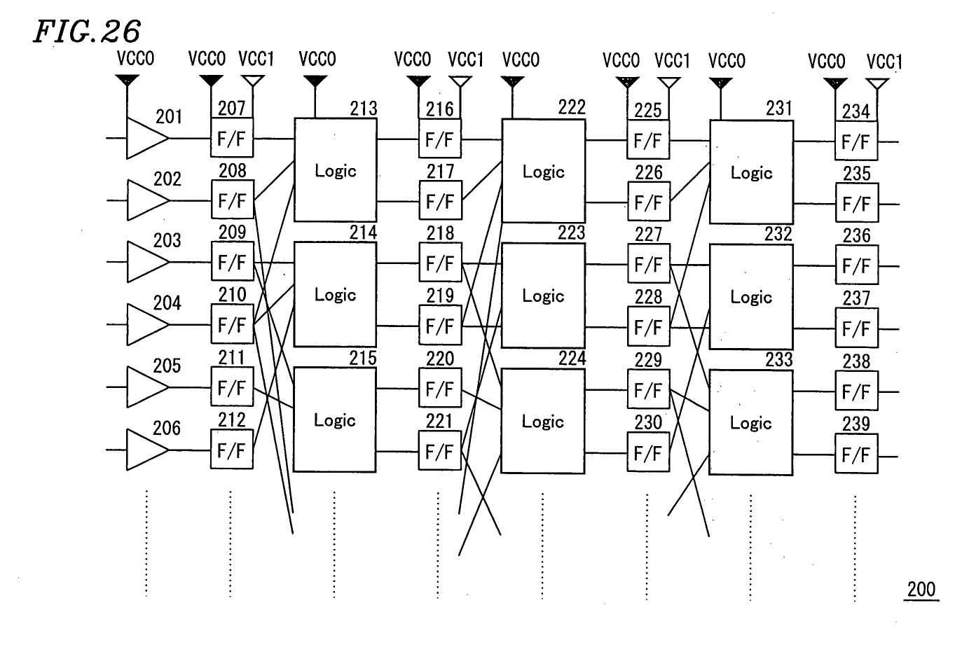

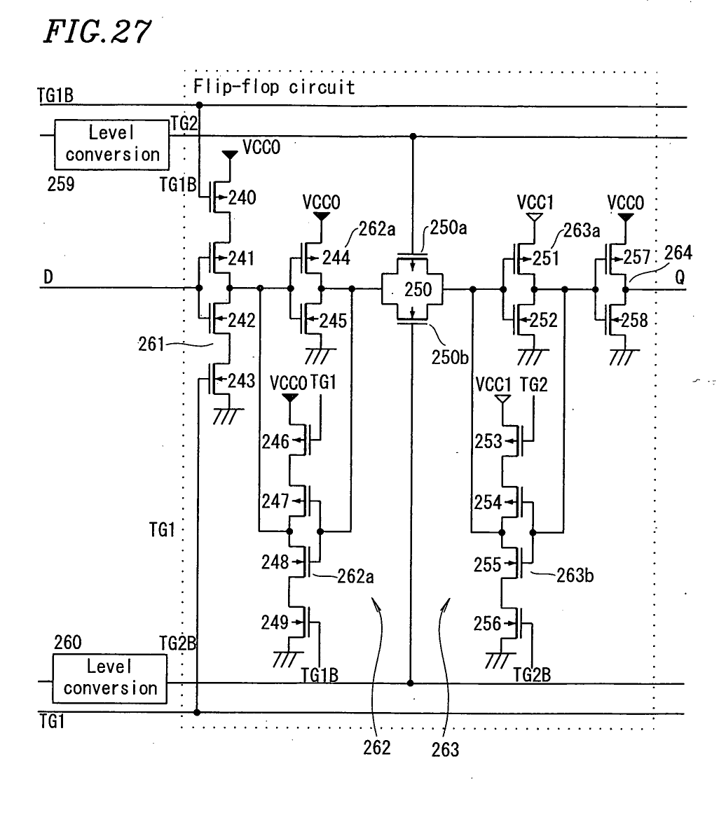

FIG. 22 is a cross-sectional view showing a structure of an SOI-structure transistor.

In the SOI structure of FIG. 22, elements are separated from a substrate 17 by a buried oxide film 18. A transistor is formed in a thin film Si on the buried oxide film 18. An n+source region 20 and an n+drain region 22 are provided on opposite sides of a p-type body region 21 which will become a transistor channel. A gate oxide film 23 is provided from the source region 20 to the drain region 22. A gate electrode 24 is provided on the gate oxide film 23, overlapping the body region 21.

In the SOI structure, the source region 20 and the drain region 22 are surrounded by an oxide film 19. Therefore, the junction capacitance of the transistor is small and low power consumption can be achieved. The SOI structure transistor has a steep sub-threshold characteristic. Therefore, even when a source-drain voltage is low, a large current can be obtained compared to a bulk MOS device or the like. Therefore, the SOI structure transistor is suitable for a pass transistor logic circuit. Therefore, by using the SOI structure transistor, it is possible to achieve a semiconductor integrated circuit having lower power consumption.

In addition, the SOI structure transistor can have a low threshold voltage due to the steep sub-threshold characteristic, thereby making it possible to achieve a semiconductor integrated circuit having a low voltage operation. When a pass transistor logic gate is made of CMOS in order to achieve a low voltage operation, an increase in area and parasitic capacitance can be considerably reduced as compared to the bulk structure, resulting in further miniaturization of circuits.

(Embodiment 12)

In Embodiment 11, the present invention is applied to the standard cell scheme. The present invention may be applied to the gate array scheme. In Embodiment 12, an information processing apparatus within a computer fabricates a desired logic circuit based on a gate array scheme logic circuit synthesis control program. More specifically, a logic circuit is automatically synthesized based on the program by determining wiring patterns within and between basic cells using a substrate on which a plurality of basic cells are provided. The basic cell includes a first cell comprising a plurality of transistors constituting a pass transistor logic network and a second cell comprising two PMOS transistors connected in series and two NMOS transistors connected in series.

In the gate array scheme, a substrate is prepared, in which a number of arrays of basic cells comprising a plurality of transistors have been neatly arranged to fabricate a basic gate before the step of forming metal conductors; and the transistors are connected with conductors using a computer system 40 shown in FIG. 3 to fabricate a desired logic circuit.

The ROM 41 stores the gate array scheme logic circuit synthesis control program; information about arrangement of transistors constituting basic cells; information about positions of the terminals of a transistor; wiring information for fabricating a basic gate using basic cells; and information about basic cells. The CPU 42 determines a wiring pattern of conductors interconnecting transistors in basic cells using information about the basic cells based on the gate array scheme logic circuit synthesis control program read out from the ROM 41 (i.e., the position of a basic gate is determined), and also determines a wiring pattern of conductors interconnecting basic gates. In this case, the wiring pattern is designed in such a manner that circuit specification, design constraints, or the like input from the manipulation section 44 is satisfied, the total length of conductors between each basic gate is short and the wiring pattern is simple. The thus-obtained wiring pattern is transcribed onto one or more layers of metal wiring mask. With this mask, conductors interconnecting transistors within basic cells and conductors interconnecting basic gates are fabricated. As a result, a semiconductor integrated circuit is fabricated.

FIG. 23 is a layout diagram showing a cell array pattern of the semiconductor integrated circuit of Embodiment 12.

Here, a plurality of cell arrays 26 to 30 are provided on a semiconductor chip 30. Each of the cell arrays 26 to 30 comprises: a first cell S1 for a pass transistor logic network comprising a plurality of NMOS transistors (FIG. 1A) or transistors comprising a pair of an NMOS transistor and a PMOS transistor (FIG. 8A); and a second cell S2 comprising PMOS transistors connected in series and NMOS transistors connected in series (FIG. 1B), as described in the embodiments above.

For example, a plurality of pass transistor logic network first cells are provided in the cell array 26, 28, and 30, and a plurality of second cells comprising transistors connected in series are provided in the cell arrays 27 and 29. Alternatively, a plurality of pass transistor logic network first cells and a plurality of second cells comprising transistors connected in series may be provided in the cell arrays 26 to 30.

Thus, two types of basic cells are provided on the semiconductor chip 30 at an arbitrary ratio thereof. Using these basic cells, transistors are interconnected within the cells via a lower wiring layer, and basic gates are interconnected via an upper wiring layer. Thus, the gate array scheme can be used to fabricate the same logic circuits as those described in Embodiments 1 to 11.

According to Embodiment 12, a semiconductor integrated circuit of the present invention can be achieved using the gate array scheme.

As described above, according to Embodiments 1 to 12, the standard cell scheme or the gate array scheme can be used to fabricate a logic operation circuit using the first cell S1 comprising a plurality of transistors M01 to M04 constituting a pass transistor logic network; a driver circuit for driving the logic operation circuit using the second cell S2 comprising the series connection PMOS transistor section M05 and the series connection NMOS transistor section M06; a data retaining circuit for retaining data output from the logic operation circuit; and the like. Therefore, a plurality of types of logic functions can be achieved with smaller size cells and a smaller number of types of cells. The second cell comprises transistors connected in series and therefore a source-drain voltage is divided. Therefore, a leakage current can be significantly reduced as compared to a single transistor. In addition, a conventional source voltage switch is not used. Therefore, an influence of IR drop due to a source voltage switch during operations is removed, thereby making it possible to improve operating characteristics.

As described above, according to the present invention, two types of cell structures, i.e., a first cell comprising a plurality of transistors constituting a pass transistor logic network and a second cell comprising two PMOS transistors connected in series and two NMOS transistors connected in series, are prepared in a library. By using the standard cell scheme, a semiconductor integrated circuit having low power consumption can be easily achieved.

According to the present invention, two types of cell structures, i.e., a first cell comprising a plurality of transistors constituting a pass transistor logic network and a second cell comprising two PMOS transistors connected in series and two NMOS transistors connected in series, are fabricated on a substrate, and circuit connection is performed via an upper wiring layer. By using the gate array scheme, a semiconductor integrated circuit having low power consumption can be easily achieved.

According to the present invention, a first cell is used to construct a logic operation circuit, and a second cell is used to construct a driver circuit (e.g., an inverter buffer circuit) for driving a logic operation circuit, a data retaining circuit (e.g., a latch circuit, a flip-flop circuit, etc.) for retaining data output by the logic operation circuit, or the like. The second cell comprises transistors connected in series, so that a leakage current can be reduced as compared to a single transistor. Therefore, a leakage current in a standby state can be reduced.

In the second cell, the source of the PMOS transistors connected in series is connected to a first source voltage Vdd, while the source of the NMOS transistors connected in series is connected to a second source voltage Vss (GND); the gate of the PMOS transistor closer to the source of the series circuit is connected to the gate of the NMOS transistor closer to the source of the series circuit and the gates are used as an input terminal; the gate of the PMOS transistor closer to the drain of the series circuit and the gate of the NMOS transistor closer to the drain of the series circuit are used as gate control signal input terminals; and the drain of the PMOS transistor and the drain of the NMOS transistor are connected together as an output terminal. As a result, an inverter circuit constituting a buffer circuit, a flip-flop circuit, or the like is fabricated. Thereby, the circuit can be in the “OFF” state in a standby state, thereby making it possible to prevent waste standby current flow. In addition, by controlling the transistor closer to the drain of the series circuit, current consumption due to transition feedback of an input signal can be suppressed, so that low power consumption can be achieved.

In the second cell, the source of the PMOS transistors connected in series is connected to a first source voltage Vdd, while the source of the NMOS transistors connected in series is connected to a second source voltage Vss (GND); the gate of the PMOS transistor closer to the drain is connected to the gate of the NMOS transistor closer to the drain and the gates are used as an input terminal; the gate of the PMOS transistor closer to the source and the gate of the NMOS transistor closer to the source are used as gate control signal input terminals; and the drain of the PMOS transistor and the drain of the NMOS transistor are connected together as an output terminal. As a result, an inverter circuit constituting a buffer circuit, a flip-flop circuit, or the like is fabricated. Thereby, the circuit can be in the “OFF” state in a standby state, thereby making it possible to prevent waste standby current flow. By controlling the transistors closer to the source, a higher-speed operation can be obtained with respect to a change in an input signal.

By designing the higher potential of a gate control signal input to the gate control signal input terminal to be higher than the first source voltage Vdd to which the source of the PMOS transistor section is connected, a leakage current is reduced when the PMOS transistor is in the “OFF” state. Therefore, power consumption in the standby state can be reduced. By designing the lower potential of a gate control signal input to the gate control signal input terminal to be lower than the second source voltage Vss (GND) to which the source of the NMOS transistor section is connected, a leakage current can be reduced when the NMOS transistor is in the “OFF”state. Therefore, power consumption in the standby state can be reduced.

In the second cell, one of the transistors may be a high threshold transistor. In this case, a leakage current can be further reduced as compared to when a low threshold transistor is employed. Therefore, power consumption in the standby state can be reduced.

In the second cell, one of the transistors may be provided with a body potential terminal so that a body potential can be controlled, thereby making it possible to control a threshold voltage. During the normal operation the body potential is controlled so that a threshold voltage is low and a higher-speed operation is performed. In the standby state the body potential is controlled so that a threshold voltage is high and a leakage current is reduced. Therefore, power consumption in the standby state can be reduced.

In the second cell, the gate electrode and the body electrode of one of the transistors may be connected together. In this case, the body potential is automatically controlled so that when the transistor is in the “ON” state, the threshold voltage is low, and when the transistor is in the “OFF” state, the threshold voltage is high. Thereby, when the transistor is in the “ON” state, the threshold voltage is low and a driving ability is high, whereby high-speed operation is possible. In addition, when the transistor is in the “OFF” state, the threshold voltage is high, thereby making it possible to reduce leakage current.

A data retaining circuit, a driver circuit, or the like, which is constructed using the second cell, can be controlled so that only an active circuit block is in the operating state while an inactive circuit block is in the standby state (stop state). Thereby, only a circuit block required for an operation (calculation) is operated, while other blocks are not operated. Therefore, a standby current associated with a leakage current in this situation can be reduced, whereby power is not wasted. Thus, a low power consumption semiconductor integrated circuit can be achieved.

In the present invention, a transistor may have a SOI structure. In this case, low power consumption can be achieved due to characteristics of the SOI structure, i.e., a low threshold and a low junction capacitance.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A semiconductor integrated circuit, comprising:
a first cell comprising a plurality of transistors;
a second cell comprising a PMOS transistor section and an NMOS transistor section, the PMOS transistor section comprising a first PMOS transistor and a second PMOS transistor connected to the first PMOS transistor in series, the NMOS transistor section comprising a first NMOS transistor and a second NMOS transistor connected to the first NMOS transistor in series,
wherein a predetermined scheme is used to connect between the first cell and the second cell, between the plurality of transistors in the first cell, and between the PMOS transistor section and the NMOS transistor section in the second cell.

2. A semiconductor integrated circuit according to claim 1, wherein the plurality of transistors in the first cell function as at least a part of a pass transistor logic network circuit.

3. A semiconductor integrated circuit according to claim 1, wherein the predetermined scheme is a standard cell scheme or a gate array scheme.

4. A semiconductor integrated circuit according to claim 1, wherein:
the first cell functions as a logic operation circuit for outputting data; and
the second cell functions as at least one of a driver circuit for driving the logic operation circuit or a data retaining circuit for retaining data output by the logic operation circuit.

5. A semiconductor integrated circuit according to claim 1, wherein the plurality of transistors in the first cell include a PMOS transistor or an NMOS transistor.

6. A semiconductor integrated circuit according to claim 1, wherein the plurality of transistors in the first cell include a PMOS transistor and an NMOS transistor.

7. A semiconductor integrated circuit according to claim 1, wherein the plurality of transistors in the first cell include a transistor having a threshold higher than a predetermined value.

8. A semiconductor integrated circuit according to claim 1, wherein:
the first PMOS transistor, the second PMOS transistor, the first NMOS transistor, and the second NMOS transistor each comprise a gate, a source, and a drain;
a first source voltage is applied to the source of the first PMOS transistor;
a second source voltage is applied to the source of the first NMOS transistor;
one of the gate of the first PMOS transistor and the gate of the second PMOS transistor is connected to an input terminal, an input signal being input to the input terminal, and the other is connected to a first gate control signal input terminal, a first gate control signal being input to the first gate control signal input terminal;
one of the gate of the first NMOS transistor and the gate of the second NMOS transistor is connected to the input terminal, and the other is connected to a second gate control signal input terminal, a second gate control signal being input to the second gate control signal input terminal; and
the drain of the second PMOS transistor and the drain of the second NMOS transistor are connected to an output terminal.

9. A semiconductor integrated circuit according to claim 8, wherein:
the gate of the first PMOS transistor is connected to the input terminal;
the gate of the second PMOS transistor is connected to the first gate control signal input terminal;
the gate of the first NMOS transistor is connected to the input terminal; and
the gate of the second NMOS transistor is connected to the second gate control signal input terminal.

10. A semiconductor integrated circuit according to claim 8, wherein:
the gate of the first PMOS transistor is connected to the first gate control signal input terminal;
the gate of the second PMOS transistor is connected to the input terminal;
the gate of the first NMOS transistor is connected to the second gate control signal input terminal; and
the gate of the second NMOS transistor is connected to the input terminal.

11. A semiconductor integrated circuit according to claim 8, wherein:
a potential of one of the first gate control signal and the second gate control signal, whichever is higher than that of the other, is higher than a potential of the first source voltage; and
a potential of one of the first gate control signal and the second gate control signal, whichever is lower than that of the other, is lower than a potential of the second source voltage.

12. A semiconductor integrated circuit according to claim 1, wherein:
a threshold voltage of one of the first PMOS transistor and the second PMOS transistor is higher than a threshold voltage of the other; and
a threshold voltage of one of the first NMOS transistor and the second NMOS transistor is higher than a threshold voltage of the other.

13. A semiconductor integrated circuit according to claim 1, wherein:
at least one transistor of the first PMOS transistor, the second PMOS transistor, the first NMOS transistor, and the second NMOS transistor is provided with a body potential terminal; and
a body potential of the at least one transistor is controlled via the body potential terminal.

14. A semiconductor integrated circuit according to claim 1, wherein:
at least one transistor of the first PMOS transistor, the second PMOS transistor, the first NMOS transistor, and the second NMOS transistor is provided with a body electrode; and
the body electrode is connected to the gate of the at least one transistor.

15. A semiconductor integrated circuit according to claim 8, further comprising:
an inverter circuit comprising the second cell,
wherein a clock signal is input to the first gate control signal input terminal or the second gate control signal input terminal.

16. A semiconductor integrated circuit according to claim 8, further comprising:
an inverter circuit comprising the second cell,
wherein a standby state control signal is input as the first gate control signal to the first gate control signal input terminal or as the second gate control signal to the second gate control signal input terminal, so that an operation of the inverter circuit is stopped in a standby state.

17. A semiconductor integrated circuit according to claim 1, further comprising:
a data retaining circuit comprising a combination of a plurality of circuits comprising the second cell.

18. A semiconductor integrated circuit according to claim 1, further comprising:
a circuit comprising the second cell,
wherein the circuit comprises a first block and a second block, and the circuit is controlled so that the first block is operated while the second block is in a standby state.

19. A semiconductor integrated circuit according to claim 8, further comprising:
a driver circuit comprising the second cell,
wherein the driver circuit is driven with the first gate control signal or the second gate control signal; and
the gate of the first PMOS transistor, the gate of the second PMOS transistor, the gate of the first NMOS transistor, and the gate of the second NMOS transistor are connected together.

20. A semiconductor integrated circuit according to claim 3, wherein the plurality of transistors in the first cell, and the first PMOS transistor, the second PMOS transistor, the first NMOS transistor, and the second NMOS transistor in the second cell have a SOI structure.

21. A method for fabricating a semiconductor integrated circuit, comprising the steps of:
automatically synthesizing the semiconductor integrated circuit by determining a wiring pattern between a first cell comprising a plurality of transistors and a second cell comprising a PMOS transistor section and an NMOS transistor section, a wiring pattern between the plurality of transistors in the first cell, and a wiring pattern between the PMOS transistor section and the NMOS transistor section in the second cell in accordance with a predetermined scheme using a computer, wherein the PMOS transistor section comprises a first PMOS transistor and a second PMOS transistor connected to the first PMOS transistor in series, and the NMOS transistor section comprises a first NMOS transistor and a second NMOS transistor connected to the first NMOS transistor in series; and
fabricating the automatically synthesized semiconductor integrated circuit.

22. A method according to claim 21, wherein:
the predetermined scheme includes a standard cell scheme;
the first cell and the second cell are registered as standard cells in the computer; and
the step of automatically synthesizing includes using the computer to automatically synthesize the semiconductor integrated circuit by determining the wiring pattern and wiring channel width between the first cell and the second cell, the wiring pattern and wiring channel width between the plurality of transistors in the first cell, and the wiring pattern and wiring channel width between the PMOS transistor section and the NMOS transistor section in the second cell.

23. A method according to claim 21, wherein:
the predetermined scheme includes a gate array scheme; and
the automatically synthesizing step includes automatically synthesizing the semiconductor integrated circuit comprising the first cell and the second cell by using a substrate having a plurality of basic cell arrays comprising a basic cell comprising the first cell and the second cell using the computer.
